(19) United States
(12) Patent Application Publication
(10) Pub. No.: US 2026/0319246 A1
(43) Pub. Date: Oct. 15, 2026

(54) AN ABERRATION CORRECTION OPTICAL SYSTEM

(71) Applicant: ASML Netherlands B.V., Veldhoven (NL)

(72) Inventors: Teunis Willem TUKKER, Eindhoven (NL); Peter Danny VAN VOORST, Nijmegen (NL); Zili ZHOU, Veldhoven (NL); Hendrikus Robertus Marie VAN GREEVENBROEK, Eindhoven (NL); Anton BARANIKOV, Eindhoven (NL); Mustafa Ümit ARABUL, Eindhoven (NL)

(73) Assignee: ASML Netherlands B.V., Veldhoven (NL)

(21) Appl. No.: 19/117,116

(22) PCT Filed: Sep. 14, 2023
(86) PCT No.: PCT/EP2023/075254

§ 371 Date: Mar. 31, 2025

(30) Foreign Application Priority Data
Oct. 11, 2022 (EP) 22200778.3
Dec. 28, 2022 (EP) 22217039.1
Jan. 9, 2023 (EP) 23150734.4
May 3, 2023 (EP) 23171386.8

(51) Int. Cl. G02B 27/00

(52) U.S. Cl. CPC G02B 27/0025

(57) ABSTRACT

An optical arrangement for aberration correction, comprising: a beam dispersing element for spatially dispersing a broadband radiation beam in a first transverse direction; a focusing lens for focusing the broadband radiation beam subsequently to said dispersing, wherein said focusing lens is arranged such that the dispersed broadband radiation beam passes through at least one off-center position of the focusing lens in at least one pass, wherein said off-center position is a position displaced from a center of the focusing lens in a second transverse direction, wherein the first transverse direction and the second transverse direction are mutually perpendicular and parallel to a focal plane of the focusing lens; and at least one aberration compensating lens displaced in the second transverse direction with respect to at least part of the broadband radiation beam so as to substantially compensate for lateral chromatic aberration.

### CROSS-REFERENCE TO RELATED APPLICATIONS

This application claims priority of EP Application Serial No. 22200778.3 which was filed on 11 Oct. 2022, EP Application Serial No. 22217039.1 which was filed on 28 Dec. 2022, EP Application Serial No. 23150734.4 which was filed on 9 Jan. 2023 and EP Application Serial No. 23171386.8 which was filed on 3 May 2023 which are incorporated herein in its entirety by reference.

### FIELD

The present invention relates to a broadband optical system for controlling a broadband optical beam, and in particular such a broadband optical system in relation to metrology applications in the manufacture of integrated circuits.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) at a patterning device (e.g., a mask) onto a layer of radiation-sensitive material (resist) provided on a substrate (e.g., a wafer).

To project a pattern on a substrate a lithographic apparatus may use electromagnetic radiation. The wavelength of this radiation determines the minimum size of features which can be formed on the substrate. Typical wavelengths currently in use are 365 nm (i-line), 248 nm, 193 nm and 13.5 nm. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Low-k₁ lithography may be used to process features with dimensions smaller than the classical resolution limit of a lithographic apparatus. In such process, the resolution formula may be expressed as CD=k₁×λ/NA, where λ is the wavelength of radiation employed, NA is the numerical aperture of the projection optics in the lithographic apparatus, CD is the “critical dimension” (generally the smallest feature size printed, but in this case half-pitch) and k₁ is an empirical resolution factor. In general, the smaller k₁ the more difficult it becomes to reproduce the pattern on the substrate that resembles the shape and dimensions planned by a circuit designer in order to achieve particular electrical functionality and performance. To overcome these difficulties, sophisticated fine-tuning steps may be applied to the lithographic projection apparatus and/or design layout. These include, for example, but not limited to, optimization of NA, customized illumination schemes, use of phase shifting patterning devices, various optimization of the design layout such as optical proximity correction (OPC, sometimes also referred to as “optical and process correction”) in the design layout, or other methods generally defined as “resolution enhancement techniques” (RET). Alternatively, tight control loops for controlling a stability of the lithographic apparatus may be used to improve reproduction of the pattern at low k₁.

Metrology tools are used in many aspects of the IC manufacturing process, for example as alignment tools for proper positioning of a substrate prior to an exposure, leveling tools to measure a surface topology of the substrate, for e.g., focus control and scatterometry based tools for inspecting/measuring the exposed and/or etched product in process control. In each case, a radiation source is required. For various reasons, including measurement robustness and accuracy, broadband or white light radiation sources are increasingly used for such metrology applications. It would be desirable to improve on present devices for better control (e.g., multiple wavelength or wavelength band selection, wavelength-based intensity control) of broadband radiation.

### SUMMARY

According to a first aspect of the invention, there is provided an optical arrangement for aberration correction, comprising: a beam dispersing element for spatially dispersing a broadband radiation beam in a first transverse direction; a focusing lens for focusing the broadband radiation beam subsequently to said dispersing, wherein said focusing lens is arranged such that the dispersed broadband radiation beam passes through at least one off-center position of the focusing lens in at least one pass, wherein said off-center position is a position displaced from a center of the focusing lens in a second transverse direction, wherein the first transverse direction and the second transverse direction are mutually perpendicular and parallel to a focal plane of the focusing lens; and at least one aberration compensating lens displaced in the second transverse direction with respect to at least part of the broadband radiation beam so as to substantially compensate for lateral chromatic aberration imposed by the focusing lens on the at least part of the broadband radiation beam.

According to a second aspect of the invention, there is provided a method for optimizing an optical arrangement according to the first aspect, comprising: determining an amount of aberration imposed by the focusing lens on the broadband radiation beam; and displacing the at least one aberration compensating lens with respect to the broadband radiation beam to impose an amount of counter-aberration on the broadband radiation beam so as to substantially compensate the aberration imposed by the focusing lens.

Other aspects of the invention comprise metrology device comprising an optical arrangement according the first aspect.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a schematic overview of a lithographic cell;

FIG. 3 depicts a schematic representation of holistic lithography, representing a cooperation between three key technologies to optimize semiconductor manufacturing;

FIG. 4 depicts a schematic overview of a scatterometry apparatus used as a metrology device, which may comprise a radiation source according to embodiments of the invention;

FIG. 5 depicts a schematic overview of a level sensor apparatus which may comprise a radiation source according to embodiments of the invention;

FIG. 6 depicts a schematic overview of an alignment sensor apparatus which may comprise a radiation source according to embodiments of the invention;

FIG. 7A depicts schematically transmission of a broadband optical beam through a singlet lens resulting in a large amount of lateral chromatic aberration;

FIG. 7B depicts schematically transmission of a broadband optical beam through a singlet lens resulting in a large amount of axial chromatic aberration;

FIG. 7C depicts schematically transmission of a broadband optical beam through an achromatic lens resulting in a significantly lower amount of chromatic aberration;

FIG. 8A shows a top view of a broadband optical arrangement comprising a beam dispersing element for spatially dispersing a broadband optical beam and an optical lens for focusing the dispersed broadband optical beam into a plurality focus spots;

FIG. 8B shows a side view of the broadband optical arrangement of FIG. 8A wherein the dispersed broadband optical beam travels through the center of the optical lens in the Y direction;

FIG. 8C shows a side view of the broadband optical arrangement of FIG. 8A wherein the dispersed broadband optical beam travels through an off-center position of the optical lens in the Y direction;

FIG. 9A shows different focus spots of different wavelengths in the focal plane of the optical lens when arranged for on-axis focusing in the Y direction (e.g., as shown in FIG. 8B);

FIG. 9B shows different focus spots of different wavelengths λ₁, λ₂, λ₃, λ₄, λ₅ in the focal plane of the optical lens when arranged for off-axis focusing in the Y direction (e.g., as shown in FIG. 8C);

FIG. 10A shows a top view of a grating light valves (GLV) based wavelength selector configured for zeroth order mode operation, wherein a broadband optical beam passes through an achromatic lens two times both at an off-center position in the Y direction;

FIG. 10B shows a side view of the GLV based wavelength selector configured for zeroth order mode operation (e.g., as shown in FIG. 10A) and a spot diagram showing simulated focus spots of the output beam;

FIG. 11(a) shows a top view of a grating light valve;

FIG. 11(b) shows an end-on view of the grating light valve (e.g., as shown in FIG. 11(a)) in a first configuration;

FIG. 11(c) shows an end-on view of the grating light valve in a second configuration;

FIG. 12 shows a side view of a GLV based wavelength selector in accordance with an embodiment and a spot diagram showing simulated focus spots of the output beam, wherein a broadband optical beam passes through an achromatic lens two times both at an off-center position in the Y direction and an output lens is displaced in the Y direction to optimize the overlapping of focus spots of output beam;

FIG. 13 shows a side view of another GLV based wavelength selector in accordance with an embodiment and a spot diagram showing simulated focus spots of the output beam, wherein a broadband optical beam passes through an achromatic lens two times with only the second pass being at an off-center position in the Y direction and an output lens is displaced in the Y direction to optimize the overlapping of focus spots of output beam;

FIG. 14(a) depicts schematically one example of diffraction-based overlay metrology devices;

FIG. 14(b) is a representation of an illumination pupil;

FIG. 14(c) is a representation of a detection pupil;

FIG. 14(d) shows the arrangement of the imaging lens with respect to the four quarters of the detection pupil;

FIG. 14(e) shows an example image of the overlay target;

FIG. 15(a) depicts schematically one example of diffraction-based overlay metrology devices equipped with four aberration compensating lenses;

FIG. 15(b) is a representation of an illumination pupil;

FIG. 15(c) is a representation of a detection pupil;

FIG. 15(d) shows the arrangement of the four aberration compensating lenses with respect to the four quarters of the detection pupil;

FIG. 15(e) shows an example image of the overlay target;

FIG. 16 depicts a block diagram of a computer system for controlling a broadband radiation source

FIG. 17(a) shows a tope view of a first example situation where the incident optical beam is aligned to the central region of the GLV ribbons;

FIG. 17(b) shows a side view of a first example situation where the incident optical beam is aligned to the central region of the GLV ribbons;

FIG. 17(c) shows a top view of a second example situation where the incident optical beam is aligned to an off-center position closer to one edge of the GLV ribbons;

FIG. 17(d) shows a side view of a second example situation where the incident optical beam is aligned to an off-center position closer to one edge of the GLV ribbons;

FIG. 18 shows a plot of measured optical contrast of a GLV against relative position or spot offset of an incident optical beam with respect to the center of GLV ribbons;

FIGS. 19(a) and 19(b) schematically depict another example situation where an elliptical broadband radiation beam is focused to an off-center position closer to one edge of the GLV ribbons;

FIG. 20A shows a top view of a GLV based wavelength selector having a reduced sensitivity on misalignment of a broadband radiation beam in accordance with an embodiment;

FIG. 20B shows a side view of the GLV based wavelength selector (e.g., as shown in FIG. 20A);

FIG. 21 schematically depicts an embodiment beam shaping assembly comprising a pair of cylindrical lenses;

FIG. 22 schematically depicts an embodiment beam shaping assembly comprising a pair of anamorphic prisms;

FIG. 23 schematically depicts an embodiment beam shaping assembly comprising an optical fiber having an elliptical core;

FIG. 24A shows a top view of a grating light valves (GLV) based wavelength selector configured for first order mode operation, wherein a broadband optical beam passes through an achromatic lens two times both at an off-center position in the Y direction;

FIG. 24B shows a side view of the grating light valves (GLV) based wavelength selector configured for first order mode operation (e.g., as shown in FIG. 24A);

FIG. 24C shows an example pupil representation of the GLV based wavelength selector configured for first order mode operation (e.g., as shown in FIG. 24A or 24B);

FIG. 25A shows a top view of another GLV based wavelength selector configured for first order mode operation, wherein a broadband optical beam passes through an achromatic lens two times with only the second pass being at an off-center position in the Y direction and an output lens is displaced in the Y direction to optimize the overlapping of focus spots of output beam; and

FIG. 25B shows a side view of the GLV based wavelength selector configured for first order mode operation (e.g., as shown in FIG. 25A).

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W-which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

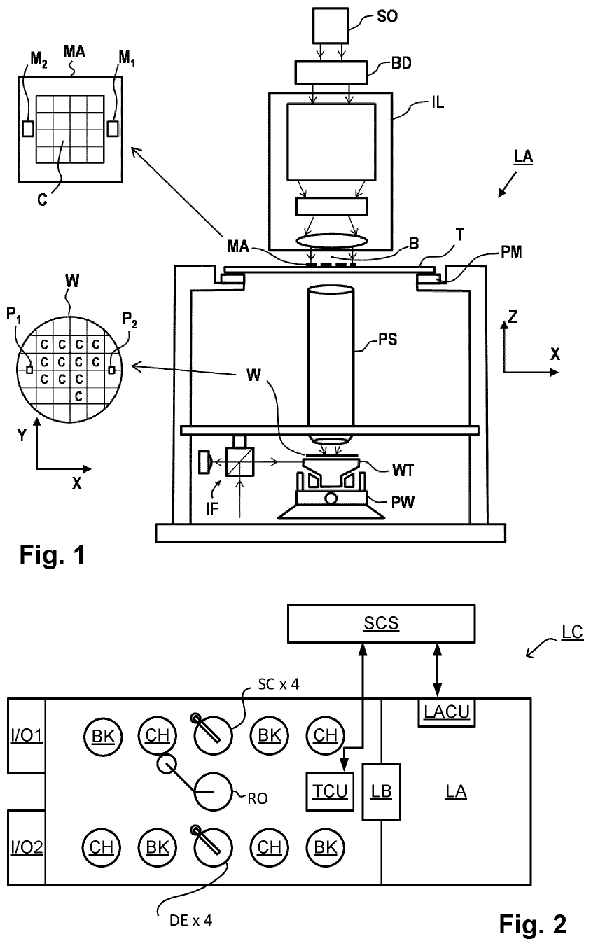

As shown in FIG. 2 the lithographic apparatus LA may form part of a lithographic cell LC, also sometimes referred to as a lithocell or (litho) cluster, which often also includes apparatus to perform pre- and post-exposure processes on a substrate W. Conventionally these include spin coaters SC to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g. via lithography control unit LACU.

In order for the substrates W exposed by the lithographic apparatus LA to be exposed correctly and consistently, it is desirable to inspect substrates to measure properties of patterned structures, such as overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties on a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching).

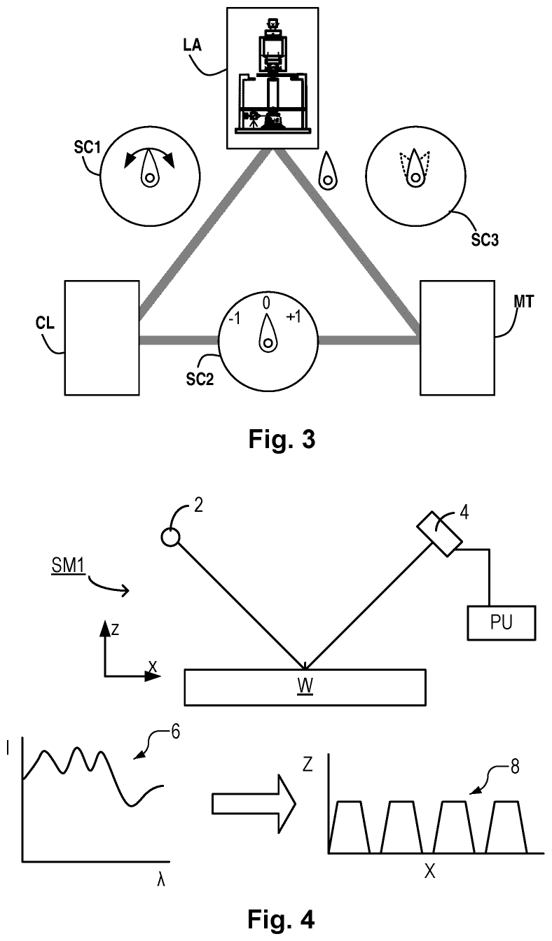

Typically the patterning process in a lithographic apparatus LA is one of the most critical steps in the processing which requires high accuracy of dimensioning and placement of structures on the substrate W. To ensure this high accuracy, three systems may be combined in a so called “holistic” control environment as schematically depicted in FIG. 3. One of these systems is the lithographic apparatus LA which is (virtually) connected to a metrology tool MT (a second system) and to a computer system CL (a third system). The key of such “holistic” environment is to optimize the cooperation between these three systems to enhance the overall process window and provide tight control loops to ensure that the patterning performed by the lithographic apparatus LA stays within a process window. The process window defines a range of process parameters (e.g. dose, focus, overlay) within which a specific manufacturing process yields a defined result (e.g. a functional semiconductor device)—typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g. using input from the metrology tool MT) to predict whether defects may be present due to e.g. sub-optimal processing (depicted in FIG. 3 by the arrow pointing “0” in the second scale SC2).

The metrology tool MT may provide input to the computer system CL to enable accurate simulations and predictions, and may provide feedback to the lithographic apparatus LA to identify possible drifts, e.g. in a calibration status of the lithographic apparatus LA (depicted in FIG. 3 by the multiple arrows in the third scale SC3).

In lithographic processes, it is desirable to make frequently measurements of the structures created, e.g., for process control and verification. Tools to make such measurement are typically called metrology tools MT. Different types of metrology tools MT for making such measurements are known, including scanning electron microscopes or various forms of scatterometer metrology tools MT. Scatterometers are versatile instruments which allow measurements of the parameters of a lithographic process by having a sensor in the pupil or a conjugate plane with the pupil of the objective of the scatterometer, measurements usually referred as pupil based measurements, or by having the sensor in the image plane or a plane conjugate with the image plane, in which case the measurements are usually referred as image or field based measurements. Such scatterometers and the associated measurement techniques are further described in patent applications US20100328655, US2011102753A1, US20120044470A, US20110249244, US20110026032 or EP1,628,164A, incorporated herein by reference in their entirety. Aforementioned scatterometers may measure gratings using light from soft x-ray and visible to near-IR wavelength range.

In a first embodiment, the scatterometer MT is an angular resolved scatterometer. In such a scatterometer reconstruction methods may be applied to the measured signal to reconstruct or calculate properties of the grating. Such reconstruction may, for example, result from simulating interaction of scattered radiation with a mathematical model of the target structure and comparing the simulation results with those of a measurement. Parameters of the mathematical model are adjusted until the simulated interaction produces a diffraction pattern similar to that observed from the real target.

In a second embodiment, the scatterometer MT is a spectroscopic scatterometer MT. In such spectroscopic scatterometer MT, the radiation emitted by a radiation source is directed onto the target and the reflected or scattered radiation from the target is directed to a spectrometer detector, which measures a spectrum (i.e. a measurement of intensity as a function of wavelength) of the specular reflected radiation. From this data, the structure or profile of the target giving rise to the detected spectrum may be reconstructed, e.g. by Rigorous Coupled Wave Analysis and non-linear regression or by comparison with a library of simulated spectra.

In a third embodiment, the scatterometer MT is an ellipsometric scatterometer. The ellipsometric scatterometer allows for determining parameters of a lithographic process by measuring scattered radiation for each polarization states. Such metrology apparatus emits polarized light (such as linear, circular, or elliptic) by using, for example, appropriate polarization filters in the illumination section of the metrology apparatus. A source suitable for the metrology apparatus may provide polarized radiation as well. Various embodiments of existing ellipsometric scatterometers are described in U.S. patent application Ser. Nos. 11/451,599, 11/708,678, 12/256,780, 12/486,449, 12/920,968, 12/922,587, 13/000,229, 13/033,135, 13/533,110 and 13/891,410 incorporated herein by reference in their entirety.

In one embodiment of the scatterometer MT, the scatterometer MT is adapted to measure the overlay of two misaligned gratings or periodic structures by measuring asymmetry in the reflected spectrum and/or the detection configuration, the asymmetry being related to the extent of the overlay. The two (typically overlapping) grating structures may be applied in two different layers (not necessarily consecutive layers), and may be formed substantially at the same position on the wafer. The scatterometer may have a symmetrical detection configuration as described e.g. in co-owned patent application EP1,628,164A, such that any asymmetry is clearly distinguishable. This provides a straightforward way to measure misalignment in gratings. Further examples for measuring overlay error between the two layers containing periodic structures as target is measured through asymmetry of the periodic structures may be found in PCT patent application publication no. WO 2011/012624 or US patent application US20160161863, incorporated herein by reference in its entirety.

Other parameters of interest may be focus and dose. Focus and dose may be determined simultaneously by scatterometry (or alternatively by scanning electron microscopy) as described in US patent application US2011-0249244, incorporated herein by reference in its entirety. A single structure may be used which has a unique combination of critical dimension and sidewall angle measurements for each point in a focus energy matrix (FEM—also referred to as Focus Exposure Matrix). If these unique combinations of critical dimension and sidewall angle are available, the focus and dose values may be uniquely determined from these measurements.

A metrology target may be an ensemble of composite gratings, formed by a lithographic process, mostly in resist, but also after etch process for example. Typically the pitch and line-width of the structures in the gratings strongly depend on the measurement optics (in particular the NA of the optics) to be able to capture diffraction orders coming from the metrology targets. As indicated earlier, the diffracted signal may be used to determine shifts between two layers (also referred to ‘overlay’) or may be used to reconstruct at least part of the original grating as produced by the lithographic process. This reconstruction may be used to provide guidance of the quality of the lithographic process and may be used to control at least part of the lithographic process. Targets may have smaller sub-segmentation which are configured to mimic dimensions of the functional part of the design layout in a target. Due to this sub-segmentation, the targets will behave more similar to the functional part of the design layout such that the overall process parameter measurements resembles the functional part of the design layout better. The targets may be measured in an underfilled mode or in an overfilled mode. In the underfilled mode, the measurement beam generates a spot that is smaller than the overall target. In the overfilled mode, the measurement beam generates a spot that is larger than the overall target. In such overfilled mode, it may also be possible to measure different targets simultaneously, thus determining different processing parameters at the same time.

Overall measurement quality of a lithographic parameter using a specific target is at least partially determined by the measurement recipe used to measure this lithographic parameter. The term “substrate measurement recipe” may include one or more parameters of the measurement itself, one or more parameters of the one or more patterns measured, or both. For example, if the measurement used in a substrate measurement recipe is a diffraction-based optical measurement, one or more of the parameters of the measurement may include the wavelength of the radiation, the polarization of the radiation, the incident angle of radiation relative to the substrate, the orientation of radiation relative to a pattern on the substrate, etc. One of the criteria to select a measurement recipe may, for example, be a sensitivity of one of the measurement parameters to processing variations. More examples are described in US patent application US2016-0161863 and published US patent application US 2016/0370717A1 incorporated herein by reference in its entirety.

A metrology apparatus, such as a scatterometer, is depicted in FIG. 4. It comprises a broadband (white light) radiation projector 2 which projects radiation onto a substrate 6. The reflected or scattered radiation is passed to a spectrometer detector 4, which measures a spectrum 10 (i.e. a measurement of intensity as a function of wavelength) of the specular reflected radiation. From this data, the structure or profile giving rise to the detected spectrum may be reconstructed by processing unit PU, e.g. by Rigorous Coupled Wave Analysis and non-linear regression or by comparison with a library of simulated spectra as shown at the bottom of FIG. 3. In general, for the reconstruction, the general form of the structure is known and some parameters are assumed from knowledge of the process by which the structure was made, leaving only a few parameters of the structure to be determined from the scatterometry data. Such a scatterometer may be configured as a normal-incidence scatterometer or an oblique-incidence scatterometer.

Overall measurement quality of a lithographic parameter via measurement of a metrology target is at least partially determined by the measurement recipe used to measure this lithographic parameter. The term “substrate measurement recipe” may include one or more parameters of the measurement itself, one or more parameters of the one or more patterns measured, or both. For example, if the measurement used in a substrate measurement recipe is a diffraction-based optical measurement, one or more of the parameters of the measurement may include the wavelength of the radiation, the polarization of the radiation, the incident angle of radiation relative to the substrate, the orientation of radiation relative to a pattern on the substrate, etc. One of the criteria to select a measurement recipe may, for example, be a sensitivity of one of the measurement parameters to processing variations. More examples are described in US patent application US2016/0161863 and published US patent application US 2016/0370717A1 incorporated herein by reference in its entirety.

Another type of metrology tool used in IC manufacture is a topography measurement system, level sensor or height sensor. Such a tool may be integrated in the lithographic apparatus, for measuring a topography of a top surface of a substrate (or wafer). A map of the topography of the substrate, also referred to as height map, may be generated from these measurements indicating a height of the substrate as a function of the position on the substrate. This height map may subsequently be used to correct the position of the substrate during transfer of the pattern on the substrate, in order to provide an aerial image of the patterning device in a properly focus position on the substrate. It will be understood that “height” in this context refers to a dimension broadly out of the plane to the substrate (also referred to as Z-axis). Typically, the level or height sensor performs measurements at a fixed location (relative to its own optical system) and a relative movement between the substrate and the optical system of the level or height sensor results in height measurements at locations across the substrate.

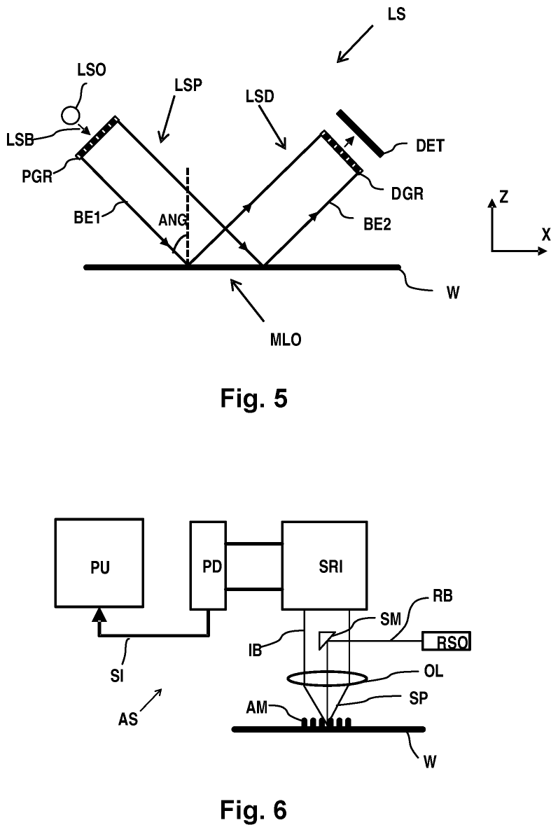

An example of a level or height sensor LS as known in the art is schematically shown in FIG. 5, which illustrates only the principles of operation. In this example, the level sensor comprises an optical system, which includes a projection unit LSP and a detection unit LSD. The projection unit LSP comprises a radiation source LSO providing a beam of radiation LSB which is imparted by a projection grating PGR of the projection unit LSP. The radiation source LSO may be, for example, a narrowband or broadband light source, such as a supercontinuum light source, polarized or non-polarized, pulsed or continuous, such as a polarized or non-polarized laser beam. The radiation source LSO may include a plurality of radiation sources having different colors, or wavelength ranges, such as a plurality of LEDs. The radiation source LSO of the level sensor LS is not restricted to visible radiation, but may additionally or alternatively encompass UV and/or IR radiation and any range of wavelengths suitable to reflect from a surface of a substrate.

The projection grating PGR is a periodic grating comprising a periodic structure resulting in a beam of radiation BE1 having a periodically varying intensity. The beam of radiation BE1 with the periodically varying intensity is directed towards a measurement location MLO on a substrate W having an angle of incidence ANG with respect to an axis perpendicular (Z-axis) to the incident substrate surface between 0 degrees and 90 degrees, typically between 70 degrees and 80 degrees. At the measurement location MLO, the patterned beam of radiation BE1 is reflected by the substrate W (indicated by arrows BE2) and directed towards the detection unit LSD.

In order to determine the height level at the measurement location MLO, the level sensor further comprises a detection system comprising a detection grating DGR, a detector DET and a processing unit (not shown) for processing an output signal of the detector DET. The detection grating DGR may be identical to the projection grating PGR. The detector DET produces a detector output signal indicative of the light received, for example indicative of the intensity of the light received, such as a photodetector, or representative of a spatial distribution of the intensity received, such as a camera. The detector DET may comprise any combination of one or more detector types.

By means of triangulation techniques, the height level at the measurement location MLO can be determined. The detected height level is typically related to the signal strength as measured by the detector DET, the signal strength having a periodicity that depends, amongst others, on the design of the projection grating PGR and the (oblique) angle of incidence ANG.

The projection unit LSP and/or the detection unit LSD may include further optical elements, such as lenses and/or mirrors, along the path of the patterned beam of radiation between the projection grating PGR and the detection grating DGR (not shown).

In an embodiment, the detection grating DGR may be omitted, and the detector DET may be placed at the position where the detection grating DGR is located. Such a configuration provides a more direct detection of the image of the projection grating PGR.

In order to cover the surface of the substrate W effectively, a level sensor LS may be configured to project an array of measurement beams BE1 onto the surface of the substrate W, thereby generating an array of measurement areas MLO or spots covering a larger measurement range.

Various height sensors of a general type are disclosed for example in U.S. Pat. Nos. 7,265,364 and 7,646,471, both incorporated by reference. A height sensor using UV radiation instead of visible or infrared radiation is disclosed in US2010233600A1, incorporated by reference. In WO2016102127A1, incorporated by reference, a compact height sensor is described which uses a multi-element detector to detect and recognize the position of a grating image, without needing a detection grating.

Another type of metrology tool used in IC manufacture is an alignment sensor. A critical aspect of performance of the lithographic apparatus is therefore the ability to place the applied pattern correctly and accurately in relation to features laid down in previous layers (by the same apparatus or a different lithographic apparatus). For this purpose, the substrate is provided with one or more sets of marks or targets. Each mark is a structure whose position can be measured at a later time using a position sensor, typically an optical position sensor. The position sensor may be referred to as “alignment sensor” and marks may be referred to as “alignment marks”.

A lithographic apparatus may include one or more (e.g. a plurality of) alignment sensors by which positions of alignment marks provided on a substrate can be measured accurately. Alignment (or position) sensors may use optical phenomena such as diffraction and interference to obtain position information from alignment marks formed on the substrate. An example of an alignment sensor used in current lithographic apparatus is based on a self-referencing interferometer as described in U.S. Pat. No. 6,961,116. Various enhancements and modifications of the position sensor have been developed, for example as disclosed in US2015261097A1. The contents of all of these publications are incorporated herein by reference.

FIG. 6 is a schematic block diagram of an embodiment of a known alignment sensor AS, such as is described, for example, in U.S. Pat. No. 6,961,116, and which is incorporated by reference. Radiation source RSO provides a beam RB of radiation of one or more wavelengths, which is diverted by diverting optics onto a mark, such as mark AM located on substrate W, as an illumination spot SP. In this example the diverting optics comprises a spot mirror SM and an objective lens OL. The illumination spot SP, by which the mark AM is illuminated, may be slightly smaller in diameter than the width of the mark itself.

Radiation diffracted by the alignment mark AM is collimated (in this example via the objective lens OL) into an information-carrying beam IB. The term “diffracted” is intended to include zero-order diffraction from the mark (which may be referred to as reflection). A self-referencing interferometer SRI, e.g. of the type disclosed in U.S. Pat. No. 6,961,116 mentioned above, interferes the beam IB with itself after which the beam is received by a photodetector PD. Additional optics (not shown) may be included to provide separate beams in case more than one wavelength is created by the radiation source RSO. The photodetector may be a single element, or it may comprise a number of pixels, if desired. The photodetector may comprise a sensor array.

The diverting optics, which in this example comprises the spot mirror SM, may also serve to block zero order radiation reflected from the mark, so that the information-carrying beam IB comprises only higher order diffracted radiation from the mark AM (this is not essential to the measurement, but improves signal to noise ratios).

Intensity signals SI are supplied to a processing unit PU. By a combination of optical processing in the block SRI and computational processing in the unit PU, values for X- and Y-position on the substrate relative to a reference frame are output.

A single measurement of the type illustrated only fixes the position of the mark within a certain range corresponding to one pitch of the mark. Coarser measurement techniques are used in conjunction with this to identify which period of a sine wave is the one containing the marked position. The same process at coarser and/or finer levels may be repeated at different wavelengths for increased accuracy and/or for robust detection of the mark irrespective of the materials from which the mark is made, and materials on and/or below which the mark is provided. The wavelengths may be multiplexed and de-multiplexed optically so as to be processed simultaneously, and/or they may be multiplexed by time division or frequency division.

In this example, the alignment sensor and spot SP remain stationary, while it is the substrate W that moves. The alignment sensor can thus be mounted rigidly and accurately to a reference frame, while effectively scanning the mark AM in a direction opposite to the direction of movement of substrate W. The substrate W is controlled in this movement by its mounting on a substrate support and a substrate positioning system controlling the movement of the substrate support. A substrate support position sensor (e.g. an interferometer) measures the position of the substrate support (not shown). In an embodiment, one or more (alignment) marks are provided on the substrate support. A measurement of the position of the marks provided on the substrate support allows the position of the substrate support as determined by the position sensor to be calibrated (e.g. relative to a frame to which the alignment system is connected). A measurement of the position of the alignment marks provided on the substrate allows the position of the substrate relative to the substrate support to be determined.

Metrology tools MT, such as a scatterometer, topography measurement system, or position measurement system mentioned above may use radiation originating from a radiation source to perform a measurement. The properties of the radiation used by a metrology tool may affect the type and quality of measurements that may be performed. For some applications, it may be advantageous to use multiple radiation frequencies to measure a substrate, for example broadband radiation may be used. Multiple different frequencies may be able to propagate, irradiate, and scatter off a metrology target with no or minimal interference with other frequencies. Therefore different frequencies may for example be used to obtain more metrology data simultaneously. Different radiation frequencies may also be able to interrogate and discover different properties of a metrology target. Broadband radiation may be useful in metrology systems MT such as for example level sensors, alignment mark measurement systems, scatterometry tools, or inspection tools. A broadband radiation source may be a supercontinuum source.

In many applications such as the aforementioned metrology applications, a broadband optical system is often used to transfer a broadband output radiation from a broadband radiation source to an application plane (e.g., a wafer plane). In addition to enabling an efficient (or a low loss) transfer of a broadband radiation, such an optical system may be further configured to control or adjust one or more characteristics of the broadband output radiation so as to obtain, for example, a desired transverse beam profile, a desired temporal profile, and/or a desired spectral profile.

The broadband optical system may comprise various different reflective (e.g., optical mirrors) and/or transmissive (e.g., optical lenses) optical elements which are typically optimized for reflecting or transmitting the broadband output radiation. For example, each optical element may comprise one or more optical coatings that are either highly transmissive (in the case of a transmissive optical element) or highly reflective (in the case of a reflective optical element) at least in the wavelength range of the broadband output radiation. However, due to the impact of material absorption and/or dispersion, optical elements, in particular transmissive optical elements may become incapable of maintaining their designed performance when the spectral coverage of the broadband output radiation becomes sufficiently wide. Consequently, such performance degradation of optical elements may cause optical loss and/or distortion and thus result in changes in the characteristics of broadband output radiation that are undesirable by the downstream application. Here, material dispersion means the refractive index of the transmissive optical element varies with the wavelength of light.

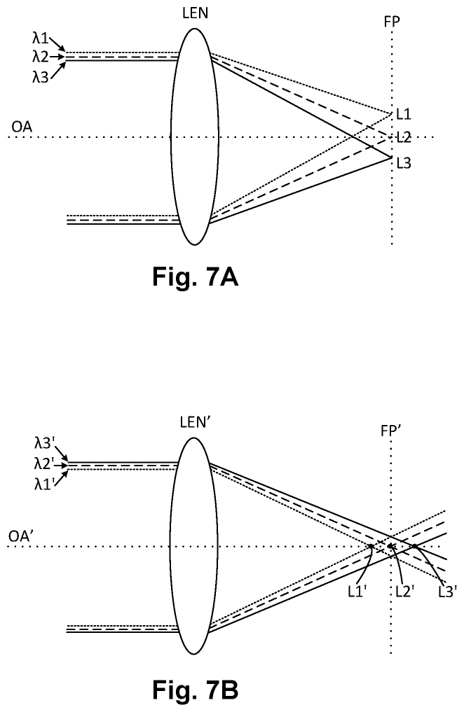

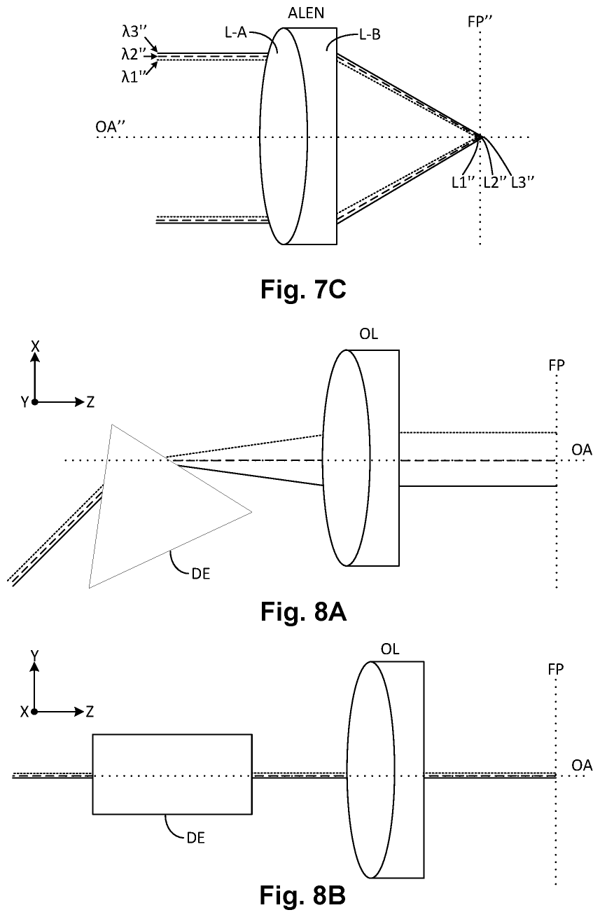

One example type of optical distortion to is chromatic aberration which occurs when an optical lens is used to focus a broadband optical beam. There are two types of chromatic aberration: lateral (or transverse) chromatic aberration and axial chromatic aberration, which are respectively illustrated in FIGS. 7A and 7B. As shown in FIG. 7A, lateral aberration occurs when different wavelengths λ₁, λ₂, λ₃ (e.g., blue, green, and red wavelengths) are focused at different transverse positions in the focal plane FP of an optical lens LEN. The lateral shift of the focal point due to a wavelength change occurs when the beams are parallel and overlapping but incident with an angle unequal to zero. Wavelength λ₂ may correspond to the designed (or nominal) wavelength at which the lens LEN is designed and manufactured. Thus, wavelength λ₂ is focused at an on-axis (i.e. on optical axis OA) position L2 in the focal plane FP, whereas other wavelengths 21 and 23 are focused at different positions L1, L3 in the focal plane FP due to the impact of material dispersion of the lens LEN. As shown in FIG. 7B, axial aberration occurs when different wavelengths λ₁′, λ₂′, λ₃′ are focused at different axial positions L1′, L2′, L3′ along the optical axis OA′ of an optical lens LEN′. Thus, different wavelengths λ₁′, λ₂′, λ₃′ correspond to different focal lengths. Here, a focal length is defined as the distance between the lens and the focus position. In this example, wavelength λ₂′ may correspond to the designed (or nominal) wavelength at which the lens LEN′ is designed and manufactured. Thus, the focus position L2′ of wavelength λ₂′ is sufficiently close the designed focus position, whereas the focus positions of other wavelengths λ₁′, λ₃′ are more deviated from the designed focus position due to the impact of material dispersion of the lens LEN′.

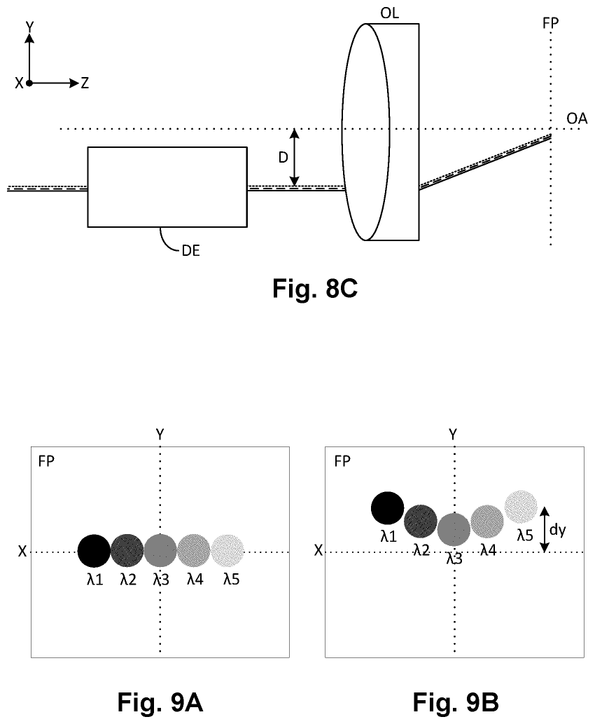

Although both types of chromatic aberration can occur together, lateral chromatic aberration is typically observed at short focal lengths while axial chromatic aberration is typically observed at long focal lengths. It is noted that the optical lenses LEN, LEN′ shown in FIGS. 7A and 7B are both singlet lenses made of one type of optical glass. To minimize or correct for chromatic aberration as well as other aberrations (e.g., spherical aberration), achromatic lenses (or achromats) have been developed and are now widely used in optical systems. An achromatic lens is a compound lens in which two or more materials with different refractive indices and different dispersions are assembled together. FIG. 7C schematically illustrates focusing of a broadband optical beam by an example achromatic lens ALEN. The example achromatic lens ALEN is formed by assembling (e.g., optical bonding) two lens elements L-A, L-B together. Such a two-element achromatic lens ALEN is also known as achromatic doublet. The two lens elements L-A, L-B may be made of for example crown glass and flint glass, respectively. As shown in FIG. 7C and in contrast to singlet lenses (e.g., as shown in FIGS. 7A and 7B), the combination of two lens elements L-A, L-B is capable of reducing or minimizing both lateral and axial chromatic aberration and consequently the focus positions L1″, L2″, L3″ of the respective wavelengths λ₁″, λ₂″, λ₃″ are much closer to each other as well as to the designed (or nominal) position. Although chromatic aberration is effectively reduced in the case of on-axis focusing (e.g., as shown in FIG. 7C), the off-axis performance of an achromatic lens may not be acceptable. This may be due to the fact that the achromatic lens ALEN is corrected at two wavelengths to have zero lateral and longitudinal primary aberrations. At other wavelengths, the achromatic lens ALEN has still (much smaller) aberrations, known as secondary color, which can lead to a shift of the focal points in the focal plane FP. More details are described below with reference to FIGS. 8A-8C and FIGS. 9A-9B.

FIGS. 8A and 8B show respectively a top view and a side view of a broadband optical arrangement comprising a beam dispersing element DE (e.g., a prism) configured to spatially disperse a broadband optical beam and an optical lens OL (e.g., an achromatic doublet as shown in FIG. 7C) configured to focus the dispersed broadband optical beam into a plurality of focus spots. The broadband optical arrangement is configured such that the broadband optical beam is spatially dispersed in the X direction and all the wavelengths of the optical beam travel through the center position of the optical lens OL in the Y direction (or the on-axis position in the Y-direction). FIG. 9A shows different focus spots of different wavelengths λ₁, λ₂, λ₃, λ₄, λ₅ in the focal plane FP of the optical lens OL when arranged for on-axis focusing in the Y direction. Since the performance (e.g., chromatic aberration) of the optical lens OL is optimized (e.g., minimized) for on-axis focusing, the position differences in the Y direction between different focus spots of different wavelengths λ₁, λ₂, λ₃, λ₄, λ₅ are therefore minimized or negligible. As such, the plurality of focus spots of different wavelengths λ₁, λ₂, λ₃, λ₄, λ₅ form a straight focus line substantially in the X direction. However, as a result of being spatially dispersed in the X direction, some wavelengths (e.g., at the periphery of the dispersed optical beam) of the broadband optical beam travel through an off-center position of the optical lens OL in the X direction and thus experience a greater amount of chromatic aberration than those travel through the center position of optical lens OL in the X direction (or the path along the optical axis OA of the optical lens OL). As such, the position differences in the X direction between different focus spots of different wavelengths λ₁, λ₂, λ₃, λ₄, λ₅ are sub-optimal (or not minimized).

FIG. 8C shows a side view of the broadband optical arrangement (e.g., as shown in FIG. 8A or 8B) wherein the dispersed broadband optical beam travels through an off-center position of the optical lens OL which is offset by a distance D in the Y-direction with respect to the optical axis OA of the optical lens OL. This means the dispersed broadband optical beam travels through an off-center position of the optical lens OL in the Y direction and consequently experiences a higher amount of chromatic aberration than the on-axis focusing scenario illustrated in FIG. 8B. FIG. 9B shows different focus spots of different wavelengths λ₁, λ₂, λ₃, λ₄, λ₅ in the focal plane FP of the optical lens OL when arranged for off-axis focusing in the Y direction. For off-axis focusing as shown in FIG. 8C, the larger the offset distance D is (or the closer the optical beam is to the periphery of the optical lens OL), the stronger aberration the optical beam will experience. As a consequence, the wavelengths (e.g., 21 and 25) that are located further away from the optical axis OA of the optical lens are more displaced or shifted in the Y direction than the ones located closer to (e.g., 22 and 24) or on (e.g., 23) the optical axis OA. As such, the plurality of focus spots of different wavelengths λ₁, λ₂, λ₃, λ₄, λ₅ form a curved focus line in the X-Y plane. The position differences in the X direction between different focus spots of different wavelengths λ₁, Δ₂, Δ₃, λ₄, λ₅ are similar to those of the on-axis focusing scenario (e.g., as shown in FIG. 9A). Note that depending on the aberration imposed by the lens OL, the plurality of focus spots of different wavelengths λ₁, λ₂, λ₃, λ₄, λ₅ can be shifted to the opposite side of the X axis (or shifted downwardly instead of upwardly as shown in FIG. 9B and they may not be symmetric about the Y-axis.

In many applications, it may be desirable to deliberately pass a broadband optical beam through an off-center position of an optical lens OL, like the off-axis focusing scenario illustrated in FIG. 8C, such that the broadband optical beam passes through the optical lens OL two or more times. Such a multi-pass arrangement obviates the need of any additional lenses (e.g., an additional collimating lens for collimating the focused broadband optical beam) and thus reduces the total number of optical elements in an optical system, thereby allowing for a lower cost and more compact system design. However, to do this the off-axis chromatic aberration should be better managed or compensated.

Assuming the optical lens is an achromatic doublet consisting of two lens elements L-A and L-B (e.g., as shown in FIG. 7C), the Y-axis displacement dy_{dC} of the focus spots can be derived as follows [J. M. Geary, “Introduction to Lens Design with Practical ZEMAX® Examples”, published by Willmann-Bell Inc., 2002, incorporated herein by reference]:

$${dy}_{d C} = y ( {( \frac{{P}_{d C}}{{V}_{d}} )}_{A} {∅}_{A} + {( \frac{{P}_{d C}}{{V}_{d}} )}_{B} {∅}_{B} ) , \qquad [ 1 ]$$

where y denotes the Y-axis offset of the entrance position of an optical beam with respect to the optical axis of the lens (e.g., the offset D shown in FIG. 8C), V_{d} denotes the Abbe number with respect to the Fraunhofer d-line; Ø_{A} and Ø_{B} denote the refractive powers of lens element L-A and lens element L-B, respectively; P_{dC} denotes the partial dispersion ratio of the lens element. To reduce or minimize the off-axis aberration, apochromat may be used. The part between the brackets of equation [1] is recognized as the condition for apochromatism which generally requires one additional lens element, i.e. at least three lens elements as opposed to a two-element achromatic lens (e.g., as shown in FIG. 7C). Note that although apochromatic doublets do exist (in the visible range), they require specific glass choices. The glasses needed are more difficult to polish and have lower refractive indices leading to larger curvatures. This limits the focal length and results in larger sphero-chromatism (i.e. spherical aberration due to wavelength changes). Therefore, typically the three lens element solution is preferred.

Due to the aging issue of conventional cemented optical lenses, wherein two or more lens elements are cemented together, it is preferable and advantageous to design and manufacture a multi-element lens in such a way that any two neighboring lens elements are interfaced with an air spacing. Transmission efficiency is one of the important parameters for a multi-element optical lens, and therefore it is desirable to use the fewest lens elements possible. This is because a higher number of lens elements means a higher number of air-glass interfaces and thus a higher transmission loss through lens elements. Designing and manufacturing an apochromatic lens that will work over a desired broadband wavelength (e.g., from 400 nm to 1600 nm) is also found to be very difficult. For example, many special glasses that are required for making an apochromatic lens are often soft and thus difficult to manufacture. Moreover, it is very challenging and sometimes impossible to fully compensate the dispersions of multiple lens elements of different glasses when the target wavelength range is too broad (e.g., from 400 nm to 1600 nm). Note that for the sake of simplicity, in the following paragraphs, the term “achromatic lens” refers specifically to achromatic lens having two lens elements or an achromatic doublet.

It is the object of the present disclosure to provide an effective and more practical approach to address the aforementioned issues. According to a first aspect of the present disclosure, there is provided an optical arrangement for aberration correction, comprising: a beam dispersing element for spatially dispersing a broadband radiation beam in a first transverse direction; a focusing lens for focusing the broadband radiation beam subsequently to said dispersing, wherein said focusing lens is arranged such that the dispersed broadband radiation beam passes through at least one off-center position of the focusing lens in at least one pass, wherein said off-center position is a position displaced from a center of the focusing lens in a second transverse direction, wherein the first transverse direction and the second transverse direction are mutually perpendicular and parallel to a focal plane of the focusing lens; and at least one aberration compensating lens displaced in the second transverse direction with respect to at least part of the broadband radiation beam so as to substantially compensate for lateral chromatic aberration imposed by the focusing lens on the at least part of the broadband radiation beam.

In an embodiment, the optical arrangement may comprise a spectral configuration element configured to selectively transmit, diffract, or reflect the at least part of the broadband radiation beam, the at least part of the broadband radiation beam comprising one or more wavelengths of the broadband radiation beam. In an embodiment, the spectral configuration element may comprise a grating light valve (GLV) comprising configurable diffractive structures for selectively reflecting or diffracting the broadband radiation beam incident thereon into the at least part of the broadband radiation beam. Accordingly, the at least part of the broadband radiation beam may be e.g., a spectrally shaped beam having been modulated by the GLV.

The embodiments below are described in relation to a wavelength selecting apparatus based on the GLV technology. However, it will be appreciated that the fundamental concept on which all the embodiments are based can be used for many other different applications.

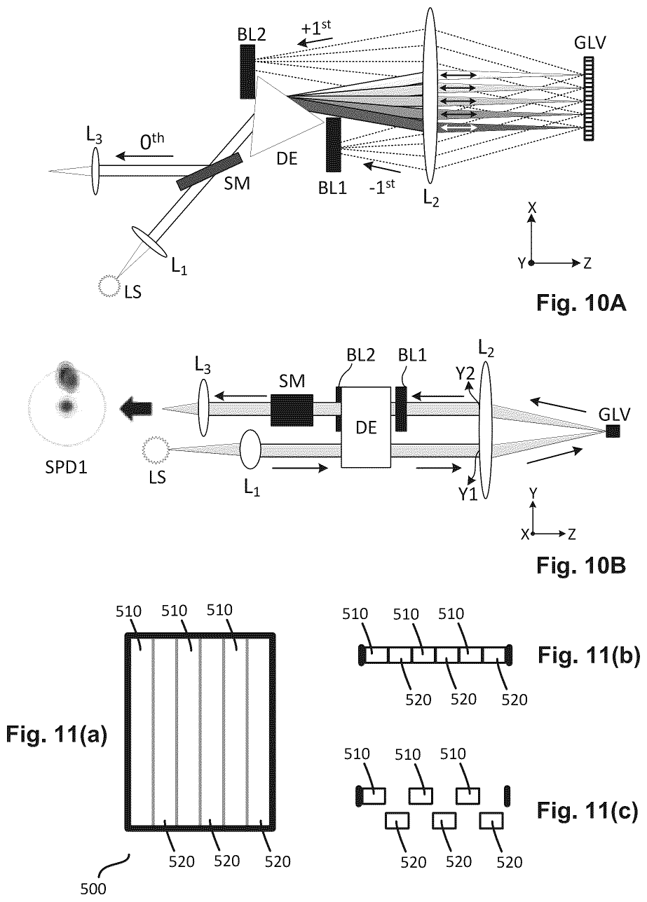

By way of example and with reference to FIGS. 10A and 10B, the example wavelength selector (also referred to as a color selection module or a source selection module) is configured such that a broadband optical beam is off-axis focused and subsequently captured by a single achromatic lens L2. The example wavelength selector uses the GLV technology such as marketed by Silicon Light Machines (SLM), and described in U.S. Pat. No. 6,947,613B, which is incorporated herein by reference. A GLV is an electrically-programmable diffraction grating based on Micro-Electro-Mechanical Systems (MEMS) technology.

FIGS. 11(a)-11(c) illustrate the working principal. FIGS. 11(a)-11(c) are schematic illustrations of a GLV pixel or component 500 from above and end-on, respectively. Please note that the GLV component shown in FIGS. 11(a)-11(c) is only an example design, other different GLV designs (e.g., the “true-GLV” design used in the G1088 and G8192 modules marketed by SLM) can also be used in the wavelength selector of FIGS. 10A and 10B. The GLV component comprises alternating GLV reflective ribbons of two types: static or bias ribbons 510 which are typically grounded along with a common electrode and driven or active ribbons 520 which are driven by an electronic driver channel. A GLV module may comprise any number of these GLV components 500 arranged in an array (e.g., a 1D or 2D array). The active and bias ribbons may be essentially identical other than in how they are driven. When no voltage is applied to the active ribbons 520, they are co-planar with the bias ribbons, a configuration illustrated in FIG. 11(b). In this configuration, the GLV acts essentially as a mirror, with incident light being specularly reflected (i.e., forming specularly reflected radiation or zeroth diffraction order radiation). When a voltage is applied to the active ribbons 520, as illustrated in FIG. 11(c), they deflect relative to the bias ribbons 510, establishing a square-well diffraction grating. In this state, incident light is diffracted into fixed diffraction angles. The ratio of light reflected with respect to light diffracted can be continuously varied by controlling the voltage on the active ribbons 520, which controls the magnitude of their deflection. As such, the amount of light diffracted by the GLV can be controlled in an analog fashion from zero (full specular reflection) to all incident light (zero specular reflection). This control of the amount of reflected radiation with respect to the amount of radiation diffracted into nonzero diffraction orders may be referred to as modulating the illumination within the context of this disclosure.

The GLV module may be used in a zeroth order mode such that the diffracted radiation is blocked/dumped and the specularly reflected (zeroth diffraction order) radiation is used. This has the advantage of preserving etendue. As such, an aperture stop or beam block may be provided in a pupil plane, or conjugate thereof, of the GLV with the aim of maximizing transmission of the zeroth order, and maximizing blocking (minimizing transmission) of the first orders (and other diffraction orders).

Referring back to FIGS. 10A and 10B, in the example wavelength selector, a broadband optical beam emitted from a broadband light source LS is dispersed in the X direction by a beam dispersing element DE, which may be for example a prism or a grating. The dispersing of the broadband optical beam is achieved based on the principle that the direction of the light emerging from the beam dispersing element DE is wavelength dependent. The broadband optical beam may be collimated by a first optical lens L₁ before being dispersed by the beam dispersing element DE. The dispersed broadband optical beam is then focused by a second optical lens L₂ onto the ribbons of the GLV which is placed substantially at the focal plane of the second lens L₂. The beam dispersing element DE and the second optical lens L₂ are arranged in much the same way as the optical arrangement shown in FIG. 8C. That is to say, the dispersed broadband optical beam travels through at a first off-center position Y1 in the Y direction (with reference to the coordinate system in FIG. 10B).

Affected by the off-axis chromatic aberration, the focus spots of different wavelengths of the broadband optical beam may form a curved focus line on the GLV (e.g., as shown in FIG. 9B) where each focus position (or focus spot) corresponds to a certain wavelength. The GLV may be configured in a zeroth order mode and is operable to apply a certain spatial modulation to the focused broadband optical beam so as to selectively reflect desired wavelengths and diffract away undesired wavelengths. In some embodiments, the GLV may be operated in a wavelength selection mode to select only one or more chosen wavelengths. That is to say, the ribbons of the GLV that correspond to the selected wavelengths may be set to equal heights such that they act like a standard mirror for the selected wavelengths. The other ribbons are actuated in such a way that they form a grating, such that undesired wavelengths incident on these ribbons are diffracted into higher diffraction orders, e.g., −1^{st} and +1^{st} diffraction orders. These higher diffraction orders are then blocked or dumped by the beam blocks BL1, BL2, respectively. The GLV may be operated also in intermediate modes, to form a grating which partially reflects and partially diffracts the incident radiation so as to attenuate but not completely block a certain wavelength. The degree of attenuation may be controlled via the ribbon configuration. In this way, the spectral constitution of the output radiation can be controlled.

The spatially modulated reflected (zeroth order) radiation from the GLV is captured by the second optical lens L₂ wherein the spatially modulated optical beam passes through the lens L₂ at a second off-center position Y2 in the Y direction. The spatially modulated optical beam is recombined on a return path using the same dispersing element DE as was used to disperse the beam on the outward path. The return path within the dispersing element DE may be substantially parallel with and displaced in the Y direction with respect to the outward path. The recombined optical beam is directed by a steering mirror SM towards a third optical lens L₃ which acts as an output lens and focuses the optical beam into a metrology device MET; e.g., via a suitable optical fiber such as a single mode photonic crystal fiber.

With reference to FIG. 10B, the spot diagram SPD1 shows a plurality of simulated focus spots of the output beam, each focus spot corresponding to a different wavelength of the output beam. The positions of the plurality of focus spots may be predominantly determined by the lateral chromatic aberration imposed by the second optical lens L₂. In an ideal case where the optical beam is free of aberrations (e.g., lateral chromatic aberration) and passes through the center of the third optical lens L₃ (i.e. on-axis focusing), the focus spots should substantially overlap with each other. However, as a result of passing through the second optical lens L₂ twice both at off-center positions, the output beam is not free of aberrations and thus the focus spots are spatially displaced with respect to each other. When such spatial displacements are on the same order as or greater than the core diameter of the transport fiber, some wavelengths may not be coupled into the fiber, thereby resulting in a significant in-coupling loss and a distortion in the spectrum of the output beam.

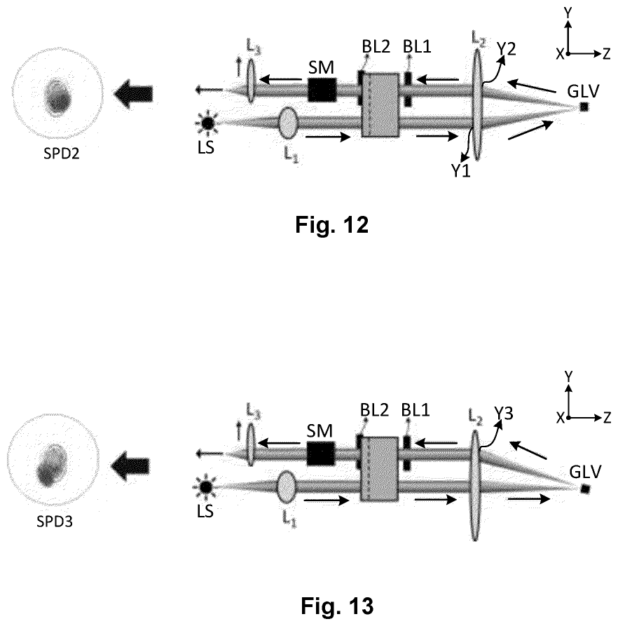

With reference to FIG. 12, an embodiment of a wavelength selector may comprise the same optical components as that shown in FIGS. 10A and 10B. The second optical lens L₂ may also be arranged in such a way that the broadband optical beam passes through the lens twice at respective different off-center positions in the Y direction (e.g., Y1 and Y2 positions). To compensate the aberrations, in particular the lateral chromatic aberration, imposed by the second optical lens L₂, the third optical lens L₃ may be displaced in the Y direction with respect to the output beam to impose a suitable amount of counter-aberration (e.g., lateral chromatic aberration) to the output beam. Note that the third optical lens L₃ can be displaced in other directions in the transverse plane (e.g., the X-Y plane defined by the coordinate system in FIG. 12) that is perpendicular to the path of the output beam. Consequently, differences in the positions of the plurality of focus spots of the output beam are minimized, as shown in the spot diagram SPD2 in FIG. 12. In other words, the focus spots of the output beam are substantially overlaid on top of each other. Note that the focus spots of the dispersed broadband optical beam may form a curved line on the GLV as a result of off-axis focusing (e.g., as shown in FIG. 8C and FIG. 9B). In some extreme cases, the focus line is may be too curved to be properly spatially modulated by the GLV.

With reference to FIG. 13, another embodiment of the wavelength selector may be arranged such that the broadband optical beam passes through the lens two times with only the second pass (or the return pass) being at an off-center position in the Y direction (e.g., Y3 position). In this embodiment, the GLV may be rotated with respect to the incident optical beam allow the reflected spatially modulated radiation to pass through the second lens L₂ at the off-center position Y3. Benefitting from on-axis focusing (on the first or outward pass), the focus spots of the dispersed broadband optical beam may form a straight line on the GLV. This may help to maintain the effectiveness of the GLV and may also relax the tolerances on the optical alignment for the GLV. Similar to the embodiment shown in FIG. 12, the third optical lens L₃ may be displaced in the Y direction with respect to the output beam to impose a suitable amount of counter-aberration (e.g., lateral chromatic aberration) to the output beam. Consequently, differences in the positions of the plurality of focus spots of the output beam are minimized, as shown in the spot diagram SPD3 in FIG. 13.

For both embodiments shown in FIGS. 12 and 13, alternatively or in addition to imposing counter-aberration via lens L₃, the first optical lens L₁ may be displaceable in the Y direction with respect to the broadband optical beam so as to introduce a suitable amount of aberration (e.g., lateral chromatic aberration) to fully or partially pre-compensate the lateral chromatic aberration imposed by the second optical lens L₂. In the case of the third optical lens L₃ being arranged for on-axis focusing, the magnitude of the lateral chromatic aberration imposed by the first optical lens L₁ may be substantially equal to the lateral chromatic aberration imposed by the second optical lens L₂. In the case of the third optical lens being configured for off-axis focusing (e.g., displaced in the Y direction with respect to the output beam), the combined magnitude of lateral chromatic aberration imposed by the first optical lens L₁ and the third optical lens L₃ may be substantially equal to the lateral chromatic aberration imposed by the second optical lens L₂. The target of the aberration compensation may be to minimize position differences between the focus spots of the output beam such that the focus spots of the optical beam after the third optical lens L₃ are substantially overlaid on top of each other. In an embodiment, the first optical lens L₁ and/or the third optical lens L₃ may be displaced in an opposite manner (e.g., displaced in an opposite direction) as compared to the displacement of the second optical lens L₂. Referring back to FIG. 12, the first optical lens L₁ may be displaced to substantially minimize the curvature of the focus line on the GLV and the third optical lens L₃ may be displaced to minimize the position differences of the plurality of focus spots of the output beam. This example implementation may have an advantage of allowing for a smaller (and thus less expensive) achromatic lens L₂ than the one employed in the embodiment of FIG. 13. However, the limitation of this implementation may be that this embodiment can only reduce or minimize the curvature of the focus line on the GLV, which means the focus line on the GLV may still be slightly curved (or have residual non-straightness). By comparison, allowing the dispersed broadband radiation to pass through the center of the second optical lens L₂ (on its first pass) can eliminate the curvature and thus produce a straight focus line on the GLV.

The broadband radiation beam may comprise a spectrum partially overlapping with the range of 200 nm to 2000 nm, or the range of 400 nm to 1600 nm. In an embodiment, the broadband radiation beam may comprise a spectrum spanning from 200 nm to 2000 nm. In an embodiment, the broadband radiation beam may comprise a spectrum spanning from 500 nm to 900 nm. The broadband radiation beam may comprise a spectrum having a full width half maximum (FWHM) width of at least 500 nm, at least 300 nm, at least 200 nm.

According to a second aspect of the present disclosure, there is provided a method for optimizing an output beam of the optical arrangement of the first aspect. The method comprising determining an amount of aberration imposed by the focusing lens on the broadband radiation beam; and displacing the at least one aberration compensating lens with respect to the broadband radiation beam to impose an amount of counter-aberration on the broadband radiation beam so as to substantially compensate the aberration imposed by the focusing lens.

In an embodiment, the at least one aberration compensating lens may be an output lens located downstream of the focusing lens, the step of determining an amount of aberration may comprise: simulating or measuring one or more positions of the output radiation at a focal plane of the output lens; and determining a wavelength dependent variation in the one or more positions of the output radiation; and calculating the amount of aberration based on the determined wavelength dependent variation in the one or more positions of the output radiation.

In an embodiment, the at least one aberration compensating lens may comprise one or both of: an output lens located downstream of the focusing lens and an input lens located upstream of the beam dispersing element, the method comprising: displacing one or both of the input lens and output lens to said amount of counter-aberration the output lens located downstream of the focusing lens and the input lens located upstream of the beam dispersing element, the method comprising: displacing the input lens to impose a second amount of counter-aberration that in combination with the counter-aberration imposed by the output lens is substantially equal to the amount of aberration imposed by the focusing lens.

It will be appreciated that the above embodiments are provided for the purpose of describing the proposed concept and are not intended to limit the scope of the present disclosure. Of course, other embodiments can be envisaged.

For example, the concept of displacing one optical lens with respect to an optical beam to compensate aberration imposed by another optical lens may be applied to diffraction-based metrology devices. Diffraction-based overlay metrology using dark field imaging of the diffraction orders enables overlay measurements on smaller targets. Examples of dark field imaging metrology can be found in international patent applications WO 2009/078708 and WO 2009/106279 which are hereby incorporated by reference in their entirety.

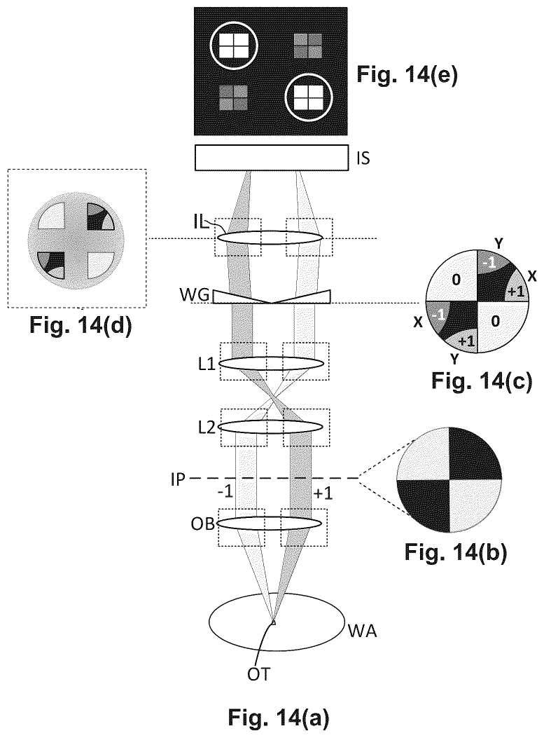

FIG. 14(a) schematically illustrates one example of a diffraction-based overlay metrology device. As shown in the figure, an overlay target OT (e.g., a micro-diffraction based overlay μDBO target) on a wafer WA is illuminated using a quartered illumination mask defining an illumination NA comprising two diagonally opposed quarters (e.g., the upper left and lower right quarters). The other two diagonally opposed quarters (e.g., the upper right and lower left quarters) are used for detection and define the detection NA. FIG. 14(b) is a representation of the illumination pupil IP of the device wherein gray quarters are used for illumination while black quarters are used for detection. In this example device, the radiation scattered from the overlay target OT comprising +1^{st}, −1^{st} and (optionally) zeroth diffraction orders are collected by the objective lens OB and then transferred through an intermediate lens assembly comprising a first lens L₁ and a second lens L₂. A 4-part wedge assembly WG is placed at the detection pupil plane of the device and arranged to redirect each of the diffraction orders (including the zeroth order if captured) to respective different beam paths and therefore to respective different detector plane locations. FIG. 14(c) is an exemplary representation of the detection pupil of the device wherein the upper left and lower right quarters of the detection pupil only contain the zeroth diffraction orders and the upper right and lower left quarters only contain the −1^{st} and +1^{st} diffractions orders. Where the overlay target OT comprises an X-pad (having a grating aligned in the X direction) and a Y-pad (having a grating aligned in the Y direction), each pad may result in a −1^{st} diffraction order and a +1^{st} diffraction order, as shown in FIG. 14(c). All the diffraction orders are then focused by an imaging lens IL onto an image sensor IS. Such an arrangement enables simultaneous imaging of the +1, −1 and zeroth orders.

FIG. 14(d) shows the corresponding areas of the imaging lens IL used for imaging the four quarters of the detection pupil to the image sensor IS. FIG. 14(e) shows an example image of the overlay target OT captured by the image sensor IS. In the detected image, the X- and Y-pads lie adjacent to each other. If aberrations are present, there will be XY crosstalk between these pads, which will negatively affect the overlay retrieval result. One group of the aberration contributors is due to the fact that the −1^{st} and +1^{st} diffraction orders go through high NA (edge) areas of a lens, where the lens quality or performance is expected to be poorer than the lower NA part (off-axis aberration described above in relation to FIG. 8C). The dashed boxes in FIG. 14 mark where the diffraction orders go through the high NA (edge) areas of the lens.

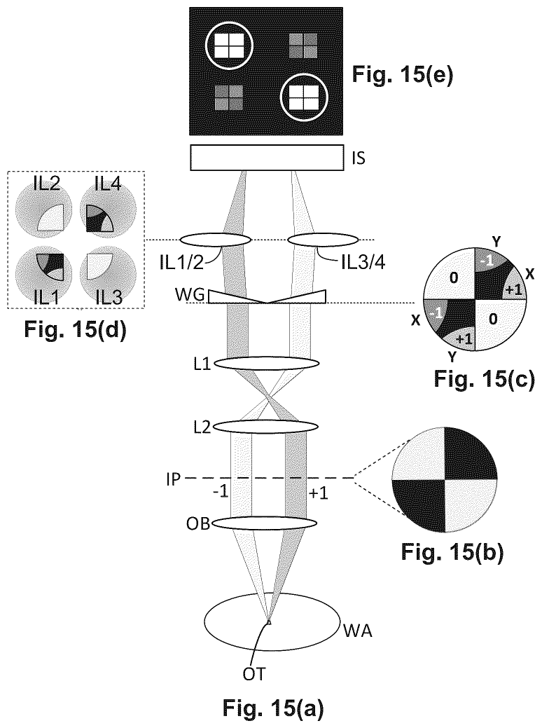

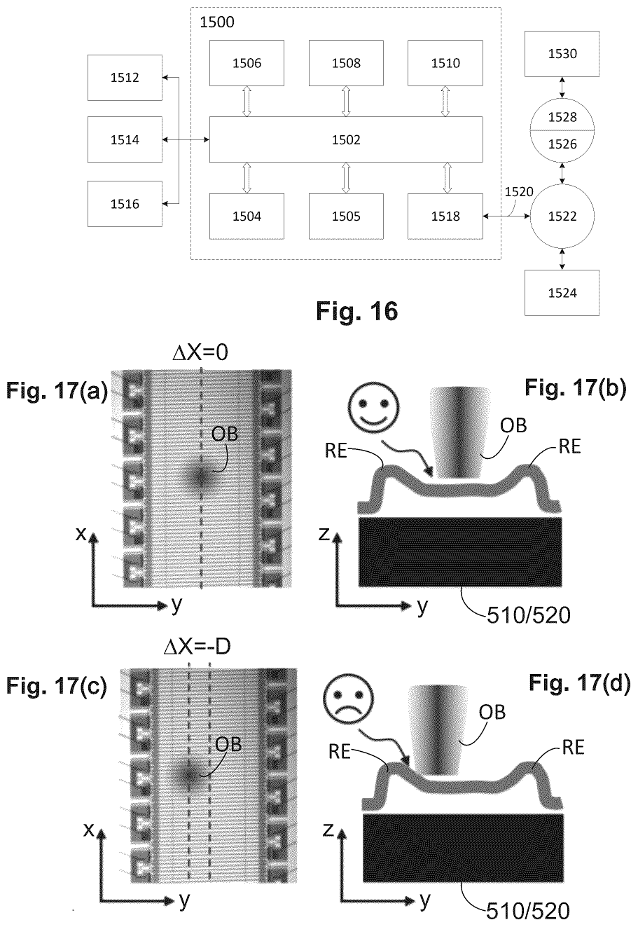

To compensate the off-axis aberration, it is proposed to replace the imaging lens IL before the image sensor IS by four separate imaging lenses IL1-IL4 (acting as aberration compensating lenses), each of which is arranged to focus one quarter of the detection pupil. FIG. 15(a) schematically illustrates one example implementation of the proposed method. Compared to the example shown in FIG. 14(a), the only change is the replacement of the single imaging lens with the four separate imaging lenses IL1-IL4. Thus, FIGS. 15(b), 15(c) and 15(e) are similar to FIGS. 14(b), 14(c) and 14(e), respectively. As shown in FIG. 15(a) and FIG. 15(d), the four imaging lenses IL1-IL4 may be individually laterally displaced with respect to their corresponding quarters such that respective radiation in each quarter of the detection pupil passes through an edge area of a respective lens IL1, IL2, IL3, IL4 in an opposite manner to that of the other lenses of the device. Here, lateral displacement refers to displacement in a transverse plane that is perpendicular to the optical axis of the device. By way of example, the lens IL1 may be laterally displaced with respect to the lower left quarter of the detection pupil in such a way that radiation within that quarter passes through the upper right area of the lens IL1. The direction of the lateral displacement of the lens IL1 may be determined based on the fact that the same radiation passes through a lower left area of each of the other lenses (e.g., the lenses OB, L2, L1) in the device. The amount of the lateral displacement and the optical properties (e.g. focal length) of the four lenses may be chosen in such a way that they compensate the aberrations induced by having the diffraction orders going through the high NA areas of the other lenses (e.g., the lenses OB, L2, L1).

In many applications, the performance of a GLV based wavelength selector is dependent on the optical contrast of the GLV. The optical contrast of a GLV is the ratio between the power of the radiation selected by the GLV with the active ribbons being applied with a first voltage that corresponds to actuation of those ribbons as much as the quarter of the corresponding wavelength (e.g., so as to provide minimum specular reflection or maximum diffraction to the incident optical beam) and the power of the radiation selected by the GLV with the active ribbons of the GLV being applied with a second voltage that sets all the ribbons to an equal height (e.g., so as to provide maximum specular reflection or minimum diffraction to the incident optical beam). For example, the wavelength selector shown in FIGS. 10A and 10B is configured to make use of the radiation selectively reflected by the GLV and block the radiation diffracted by the GLV. In such a configuration, the optical contrast may be defined as the ratio of the maximum reflected power obtained with no bias voltage applied to the minimum reflected power with the bias voltage applied. Higher optical contrast of the GLV results in better performance of the wavelength selector.

It has been found that the optical contrast of a GLV based wavelength selector (e.g., as shown in FIGS. 10A, 10B) is very sensitive to the alignment of an incident optical beam on the GLV ribbons (e.g., with respect to a central region of the GLV ribbons). Typically, when a bias voltage is applied, the GLV ribbons are not flat near their two edges (which define the length of each ribbon). Hence, the central region of the GLV ribbons may refer to the region where the ribbons are substantially flat along the length of each ribbon.

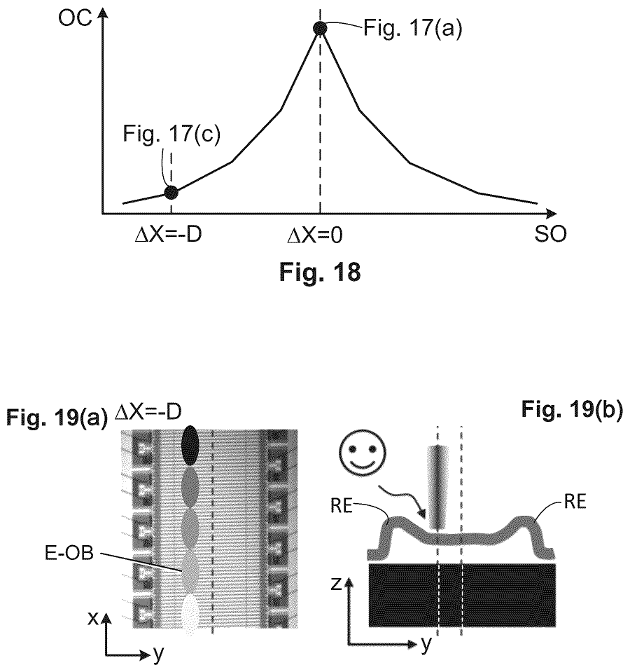

FIGS. 17(a) and 17(b) schematically depict a first example situation where the incident optical beam OB is aligned on the central region of the GLV ribbons. As shown in FIG. 17(a), each of the GLV ribbons extends along the Y direction (i.e. along the length of each ribbon) and the periodicity of the GLV ribbons is along the X direction (i.e., along the direction perpendicular to the length of each ribbon). In the example of FIGS. 17(a) and 17(b), it can be seen that the optical beam OB is incident on the flat central region of the GLV ribbons and thus sufficiently far away from the ribbon edges RE where the ribbons are no longer flat. Consequently, the optical beam OB will be subjected to an optimal phase modulation provided by the GLV ribbons and as such the optical contrast of the GLV can reach its maximum value. By contrast, FIGS. 17(c) and 17(d) schematically depict a second example situation where the incident optical beam OB is aligned to an off-center position closer to one edge RE of the GLV ribbons. In this example, part of the optical beam OB is incident on the curved edge region of the GLV ribbons and will thus be subjected to a different or suboptimal phase modulation provided by the GLV ribbons as compared to the other part of the optical beam OB incident on the flat central region of the GLV ribbons. Consequently, the optical contrast of the GLV will be lower compared to the example of FIGS. 17(a) and 17(b).

FIG. 18 shows a plot of measured optical contrast OC of a GLV against relative position or spot offset SO of an incident optical beam OB with respect to the center of GLV ribbons. The GLV is configured to selectively reflect the incident optical beam OB. As shown in the figure, the measured optical contrast OC peaks at the position where the incident optical beam OB coincides with the center of the ribbons, i.e. the spot offset SO between the optical beam and the center of the ribbons is zero, ΔX=0. This corresponds to the example situation illustrated in FIG. 17(a). The measured optical contrast OC decreases quickly as the spot offset SO increases. In the case of non-zero spot offset, e.g., ΔX=−D corresponding to the example situation illustrated in FIG. 17(c), the measured optical contrast is significantly lower than the maximum value. Therefore, it is desirable to reduce the sensitivity of a GLV on the alignment of an incident optical beam.

It is proposed, with reference to FIG. 19, to reduce the width of the incident optical beam OB along the Y direction or along the length of each ribbon, the optical contrast of the GLV becomes less sensitive to the misalignment of the optical beam OB. In other words, the optical contrast of the GLV decreases less quickly as the optical beam OB moves away from the center and towards either edge of the GLV ribbons (i.e. as the spot offset SO increases). This advantageous effect may be due to fact that the optical beam OB having a smaller beam size in the Y direction is less likely to reach the non-flat edge region RE of the ribbons when the optical beam is misaligned along the Y direction. Based on this concept, embodiments of methods and devices are disclosed herein below.

According to a third aspect of the present disclosure, there is provided an optical arrangement, comprising: a beam shaping assembly for receiving a substantially circular broadband radiation beam and outputting an elliptical broadband radiation beam with its minor axis along a first transverse direction and its major axis along a second transverse direction; a dispersing element for spatially dispersing the elliptical broadband radiation beam in the first transverse direction; a focusing lens for focusing the elliptical broadband radiation beam subsequently to said dispersing, wherein said focusing lens is arranged such that the dispersed elliptical broadband radiation beam passes through at least one off-center position of the focusing lens in at least one pass, wherein said off-center position is a position displaced from a center of the focusing lens in the second transverse direction, wherein the first transverse direction and the second transverse direction are mutually perpendicular and parallel to a focal plane of the focusing lens; and a grating light valve comprising configurable diffractive structures for selectively reflecting or diffracting the focused elliptical broadband radiation beam incident thereon into at least part of the elliptical broadband radiation beam; wherein the grating light valve is arranged such that the configurable diffractive structures extend along the first transverse direction; and wherein said beam dispersing element is further arranged to recombine the at least part of the elliptical broadband radiation beam into an output beam.

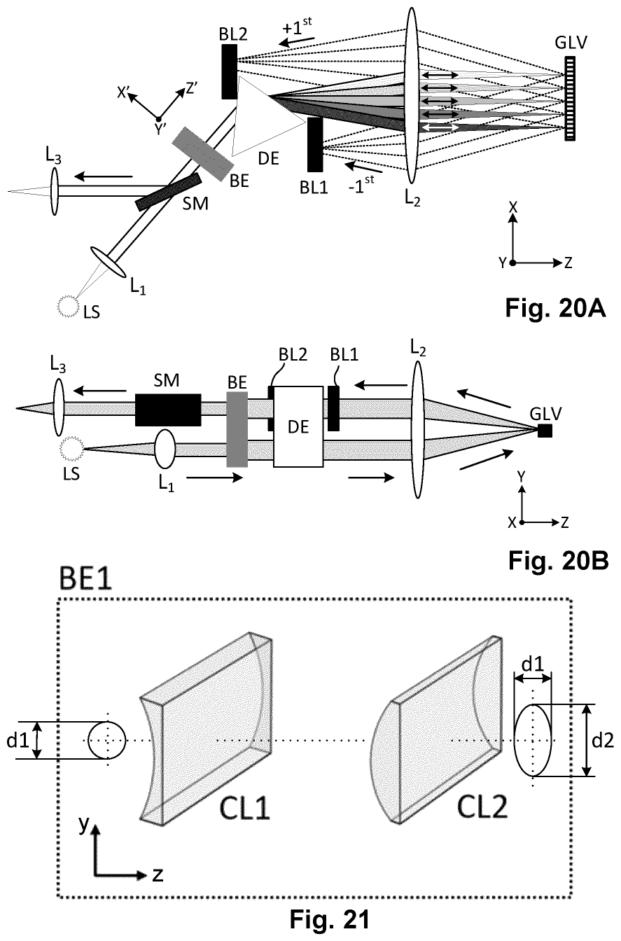

FIG. 20A shows a top view of a GLV based wavelength selector having a reduced sensitivity on misalignment of a broadband radiation beam in accordance with an embodiment. FIG. 20B shows a side view of the GLV based wavelength selector (e.g., as shown in FIG. 20A). The wavelength selector shown in FIG. 20A may comprise all the optical elements of the wavelength selector shown in FIG. 10A. Note that for the sake of simplicity, same reference signs are used to indicate same optical elements in all the figures. In addition, the wavelength selector shown in FIG. 20A may further comprise a beam shaping assembly BE configured to receive a substantially circular broadband radiation beam and output an elliptical broadband radiation beam with its minor axis and its major axis. The minor axis and major axis of the elliptical beam may coincide respectively with the X′ direction and the Y′ direction with reference to the local coordinate system next to the beam shaping assembly BE in FIG. 20A. The beam shaping assembly BE may be located upstream of the beam dispersing element DE, e.g., somewhere between the steering mirror SM and the beam dispersing element DE or somewhere between the first optical lens L1 and the light source LS.

In an embodiment, the beam shaping assembly BE may be arranged such that the diameter on the minor axis (also known as the shortest diameter) of the elliptical broadband radiation beam is substantially same as the diameter of the circular broadband radiation beam. The diameter on the major axis (also known as the longest diameter) of the elliptical broadband radiation beam may be larger than the diameter of the circular broadband radiation beam (and thus the diameter on the minor axis of the elliptical beam) by a factor of for example 2, 4, 6, 8, or 10. When such an elliptical broadband radiation beam is dispersed by the beam dispersing element DE and then focused by the achromatic lens onto the GLV, the resultant focused spots may each have an elliptical beam shape with the longest diameter being along the X direction and the shortest diameter being along the Y direction (e.g., as shown in FIG. 19). For each of the focused elliptical spots, the diameter along the X direction may be a factor of for example 2, 4, 6, 8, or 10 larger than the diameter along the Y direction. In an embodiment, the longest diameters of the focused elliptical spots on the GLV may be substantially same as or similar to the diameters of the focused circular spots (e.g., as shown in FIG. 17(a) or 17(c)) corresponding to the case where the GLV based wavelength selector comprises no beam shaping assembly BE (e.g., as shown in FIG. 10A). Such an arrangement may allow every focused elliptical spot to cover a sufficient number (e.g., 2, 4, 6, 8 or more) of GLV ribbons so as to get a decent grating phase modulation performance.

With reference to FIG. 21, in an embodiment, the beam shaping assembly BE1 may comprise a pair of cylindrical lenses, i.e. a first cylindrical lens CL1 and a second cylindrical lens CL2. The first cylindrical lens CL1 and the second cylindrical lens CL2 may be arranged to increase the diameter d1 of the broadband radiation beam along the Y direction. In an embodiment, the first and second cylindrical lenses CL1, CL2 may be arranged to substantially maintain the diameter d1 of the broadband radiation beam along the X direction. In an embodiment, the first cylindrical lens CL1 may be a plano-concave lens and the second cylindrical lens CL2 may be a plano-convex lens, said plano-concave lens being located upstream of said plano-convex lens. The beam shaping assembly BE1 may output an elliptical broadband radiation beam with the longest diameter d2 being along the Y direction and the shortest diameter d1 being along the X direction.

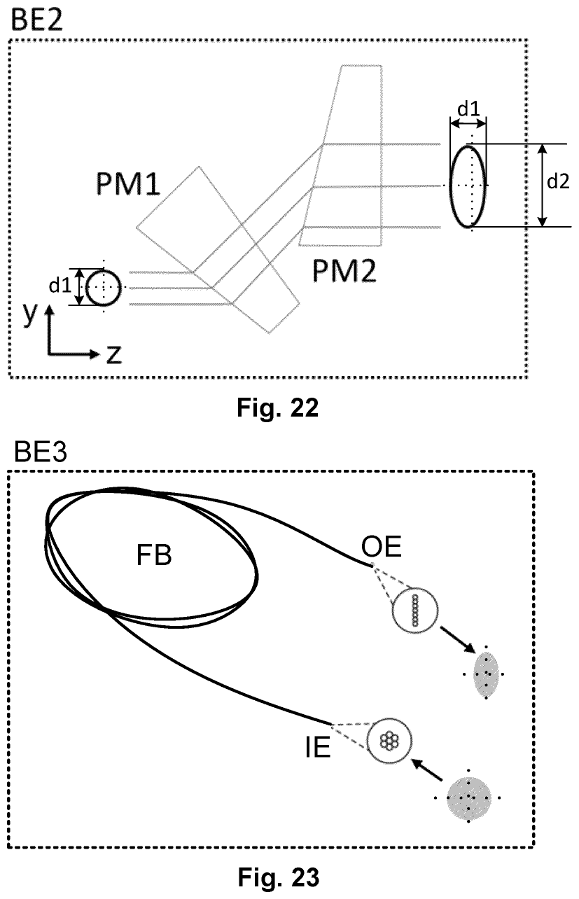

With reference to FIG. 22, in an embodiment, the beam shaping assembly BE2 may comprise a pair of prisms, i.e. a first prism PM1 and a second prism PM2, arranged to increase the diameter d1 of the broadband radiation beam along the Y direction. In an embodiment, the first and second prisms PM1, PM2 may be arranged to substantially maintain the diameter d1 of the broadband radiation beam along the X direction. In an embodiment, the first prism PM1 may be a first anamorphic prism and the second prism PM2 may be a second anamorphic prism. In an embodiment, the first anamorphic prism and the second anamorphic prism may be identical. As shown in FIG. 22, the circular broadband radiation beam may enter the first prism PM1 from a first surface at the Brewster angle (in the Y-Z plane) and may exit the first prism PM1 from a second surface at the normal angle.

The broadband radiation beam may then pass through the second prism PM2 in the same manner. While the first prism PM1 alone can change the beam radius/diameter in one axis, the second prism PM2 is helpful to manipulate the ellipticity of the radiation beam while maintaining the original direction of propagation. The beam shaping assembly BE2 may output an elliptical broadband radiation beam with the longest diameter d2 being along the Y direction and the shortest diameter d1 being along the X direction.

With reference to FIG. 23, in an embodiment, the beam shaping assembly BE3 may comprise a fiber bundle FB comprising a plurality of optical fibers (e.g., round-to-linear fiber optical bundles marketed by THORLABS). At an input end IE of the fiber bundle, the plurality of optical fibers may be arranged in a circular configuration for receiving the circular broadband radiation beam. At an output end OE of the fiber bundle, the plurality of optical fibers may be arranged in a linear configuration for outputting the elliptical broadband radiation beam. In an embodiment, each of the plurality of optical fibers may be a multimode optical fiber having a substantially circular core. In an embodiment, the beam shaping assembly BE3 may further comprise one or more optical lenses arranged to further condition or adjust beam parameters of the elliptical broadband radiation beam before it being dispersed by the beam dispersing element DE.

In an embodiment, the beam shaping assembly BE may comprise an elliptical beam mask arranged to shape the circular broadband radiation beam so as to generate the elliptical broadband radiation beam. Different to the foregoing embodiments of beam shaping assembly BE1-BE3, the elliptical beam mask (not shown) may be located upstream of the first optical lens, e.g., between the light source LS and the first optical lens. In an embodiment, the elliptical beam mask may be in the form of a plate having an elliptical-shaped aperture arranged to directly define the output beam shape by blocking part of the input circular beam. In an embodiment, the elliptical beam mask may be in the form of an optical fiber having an elliptical core (e.g., elliptical-core fibers marketed by IVG Fiber). The GLV module may be used in a first order mode such that the specularly reflected (zeroth diffraction order) radiation is blocked/dumped and the first order diffracted radiation (e.g., +1^{st} and −1^{st} orders) is used. As such, an aperture stop or beam block may be provided in a pupil plane, or conjugate thereof, of the GLV which with the aim of maximizing transmission of one or both of the first orders, and maximizing blocking (minimizing transmission) of the zeroth order.

While a GLV based wavelength selector configured for zeroth order mode operation (e.g., as shown in FIGS. 10A and 10B) is capable of delivering a good wavelength selection performance, it may be difficult for the zeroth order configuration to achieve a high out-of-band spectrum suppression ratio (or blocking ratio) required by many applications, e.g., including being used as a radiation source in metrology tools such as those illustrated in FIGS. 4 to 6. Here, the out-of-band spectrum suppression ratio is defined as the ratio of the intensity of the out-of-band leakage light over the intensity of the in-band light. The terms “out-of-band” and “in band” correspond to unwanted (or to be blocked) colors and wanted (to be selected) colors, respectively. With such a zeroth order mode configuration, there will always be a small but significant leakage of the unwanted color(s) (or out-of-band light) into the output illumination beam. For example, when configured in a zeroth order mode it is very difficult, if not impossible, to reduce leakage to significantly below 0.1% (i.e., there will typically be at least 0.1% of the incident radiation which is reflected from GLV regions configured to diffract/block all incident radiation on those regions). Such out-of-band leakage typically results from the incident light being reflected by the gaps between the GLV ribbons and/or by the protection window in front of the GLV chip and propagates in substantially the same direction as the selected zeroth order diffracted light. For metrology applications, this leakage should be at least one order of magnitude smaller than this, i.e., a suppression of at least four orders of magnitude smaller than the full signal (at least 0.01%).

Configuring the GLV ribbons to form a grating having a sufficiently high diffraction efficiency to achieve 0.01% leakage or better is difficult or impossible because there will always be gaps between the ribbons and a protection window in front of the GLV chip, which result in unwanted light being reflected. To address this limited diffraction efficiency and therefore out-of-band suppression issue, it is proposed to reverse the configuration such that the diffracted radiation (e.g., first order although other non-zero orders may be used) is used and the specular, zeroth order radiation rejected; i.e., to configure the GLV device in a “first order mode”. In such a configuration, the diffraction efficiency becomes less critical; while some diffraction inefficiency may mean some (wanted) radiation loss, it does not affect out-of-bound suppression. Very little or no radiation incident on a GLV region configured to reflect away radiation will be diffracted in the same direction(s) as the wanted first order(s), so out-of-bound suppression will be very good.

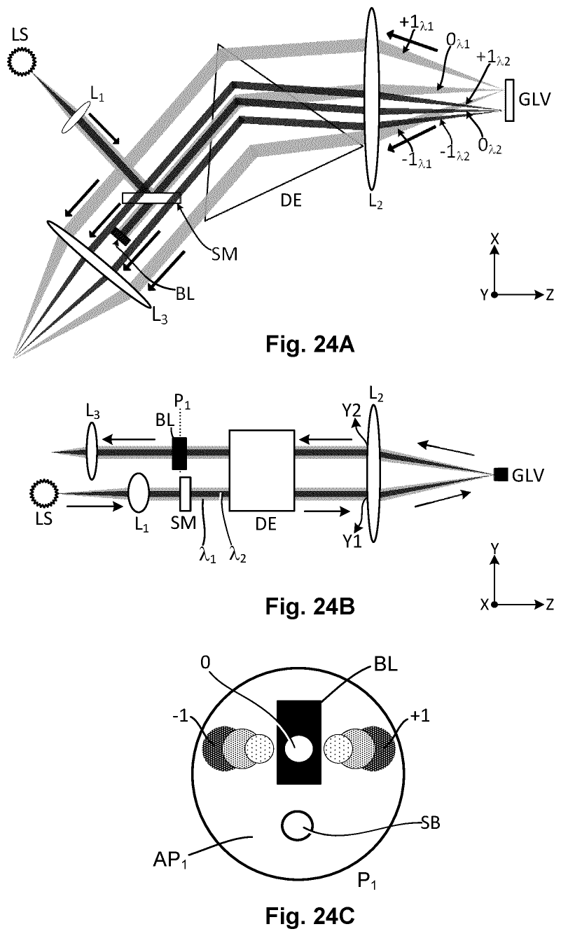

FIGS. 24A and 24B illustrate an example GLV based wavelength selector configured for first order mode operation. FIG. 24A is a top view and FIG. 24B is a side view of the arrangement. In this example, the wavelength selector is configured for first order mode operation; i.e., to transmit a source beam SB (e.g., a broadband optical beam) and the first diffraction orders selectively diffracted by the GLV module upon interacting with the broadband optical beam (only two colors +1_{λ1}, +1^{λ2}, −1_{λ1}, −1_{λ2} are shown for clarity both of which are selected by the GLV; of course there may be many more and/or a continuous spectrum), and block the zeroth diffraction order 0_{λ1}, 0_{λ2}. More specifically, in the depicted example, two wavelengths are shown being transmitted through the arrangement λ₁, λ₂ (i.e., both are selected by the GLV), with the resultant diffraction orders +1_{λ1}, −1_{λ1}, +1_{λ2}, 1_{λ2} captured by lens L₃. A beam block BL is provided in a pupil plane and arranged to maximally block the zeroth diffraction order 0_{λ1}, 0_{λ2} and maximally transmit one or both of the first diffraction orders.

Many of the components are as described in relation to FIGS. 10A and 10B and will not be described again. FIG. 24C is a pupil plane representation P₁ comprising a zeroth order stop BL positioned to block the zeroth order (specular radiation) only, thereby defining an aperture AP₁ which transmits the first orders (and/or other higher orders).

As has been explained, the beam block BL should maximize transmission of the zeroth order beams (for all selected wavelengths), and minimize transmission of the first order beams for all wavelengths or vice versa. Maximizing transmission (e.g., of the zeroth order beams or diffracted, e.g., first order beams for all wavelengths) should be understood to mean increasing transmission as much as is possible, given the limitation of the arrangement and trade-off required re minimizing transmission of the blocked radiation. Similarly, minimizing transmission (e.g., of the 1st orders or zeroth order for all wavelengths) should be understood to mean to block these orders as much as possible given these same limitations and trade-off. In particular, the fact that the spots have spatially overlapping tails (if considering a plot of intensity or amplitude against pupil position for each spot) makes it necessary to either pass some unwanted light (leading to poor out-of-band contrast) or block the tails of the wanted zero order resulting in less signal and therefore less throughput. This issue increases the larger these spots are (i.e., the greater the NA of the beam) compared to the separation of the orders.

In an embodiment, maximizing transmission may comprise transmitting 90% or more, transmitting 95% or more, transmitting 98% or more, transmitting 99% or more transmitting 99.9% or more or transmitting 99.99% or more of the transmitted radiation. In an embodiment, minimizing transmission may comprise blocking 90% or more, blocking 95% or more, blocking 98% or more, blocking 99% or more, blocking 99.9% or more or blocking 99.99% or more of the blocked radiation.

While being capable of providing a higher spectral contrast, the first order mode configuration (e.g., as shown in FIGS. 24A and 24B) suffers the similar chromatic aberration induced issues as the zeroth order mode configuration (e.g., as shown in FIGS. 10A and 10B), i.e. different wavelengths see different aberrations of the wavelength selector, leading to wavelength dependent misalignment on the GLV module and wavelength dependent variation in a position of the output beam at a focal plane of the output lens L₃. Referring back to FIG. 24B, the broadband optical beam passes the second optical lens L₂ two times both at an off-center position in the Y direction (e.g., Y1 and Y2 positions). The chromatic aberrations introduced to the broadband optical beam during its first pass through the lens L₂ result in the focus spots of different wavelengths of the incident optical beam forming a curved focus line on the GLV (e.g., as shown in FIG. 9B) where each focus position (or focus spot) corresponds to a certain wavelength. Such a curved focus line may negatively impact the spatial modulation of the GLV module. In addition, the second pass through the second lens L₂ by the first diffraction orders introduces further chromatic aberrations to the output beam. When the output lens L₃ focuses the optical beam into a metrology device MET, e.g., via a suitable optical fiber such as a single mode photonic crystal fiber, wavelength dependent position variations of the output beam will lead to high coupling losses at the fiber.

Therefore, it is proposed to apply to a wavelength selector configured for first order mode operation, the same concept of aberration correction as described above in relation to the embodiments shown in FIGS. 12 and 13; i.e., displacing at least one aberration compensating lens of the wavelength selector with respect to the broadband radiation beam to impose an amount of counter-aberration on the broadband radiation beam so as to substantially compensate the aberration imposed by a focusing lens (e.g., the second optical lens L₂) of the wavelength selector. With continued reference to FIG. 24B, in an embodiment, to compensate the aberrations (in particular the lateral chromatic aberration) imposed by the second optical lens L₂, the third optical lens L₃ may be displaced in the Y direction with respect to the output beam to impose a suitable amount of counter-aberration (e.g., lateral chromatic aberration) to the output beam. Consequently, differences in the positions of the plurality of focus spots of the output beam are minimized, in a manner similar to what is shown in the spot diagram SPD2 in FIG. 12.

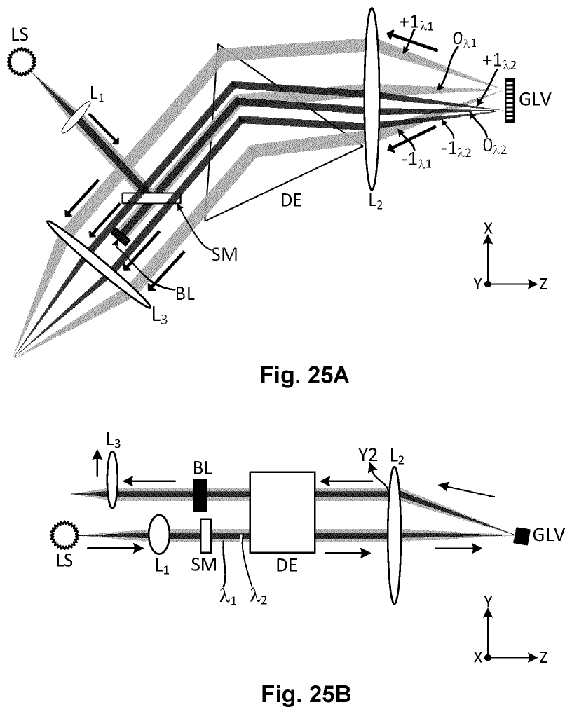

FIGS. 25A and 25B illustrate another GLV based wavelength selector configured for first order mode operation, wherein a broadband optical beam passes through an achromatic lens L₂ two times with only the second pass being at an off-center position in the Y direction (e.g., Y3 position). FIG. 25A is a top view and FIG. 25B is a side view of the arrangement. In this embodiment, the GLV module may be rotated with respect to the incident optical beam to allow the reflected spatially modulated radiation to pass through the second lens L₂ at the off-center position Y3. Benefitting from on-axis focusing (on the first or outward pass), the focus spots of the dispersed broadband optical beam may form a straight line on the GLV. This may help to maintain the effectiveness of the GLV module and may also relax the tolerances on the optical alignment for the GLV module. Similar to the embodiments shown in FIGS. 12 and 13, the third optical lens L₃ may be displaced in the Y direction with respect to the output beam to impose a suitable amount of counter-aberration (e.g., lateral chromatic aberration) to the output beam. Consequently, differences in the positions of the plurality of focus spots of the output beam are minimized, in a manner similar to what is shown in the spot diagram SPD3 in FIG. 13.

It will be appreciated that the concept of using a beam shaping assembly BE (e.g., as shown in FIGS. 20A-20B and 21-23) to shape the broadband radiation beam in such a manner that the optical contrast of the GLV module becomes less sensitive to the misalignment of the incident optical beam is also applicable to a wavelength selector configured for the first order mode operation (e.g., as shown in FIGS. 24A-24B or FIGS. 25A-25B). The technical effect of using a beam shaping assembly BE in a wavelength selector configured for the first order mode operation will be substantially the same as that in a wavelength selector configured for the zeroth order mode operation.

FIG. 15 is a block diagram that illustrates a computer system 1500 that may assist in implementing the methods and flows disclosed herein. Computer system 1500 includes a bus 1502 or other communication mechanism for communicating information, and a processor 1504 (or multiple processors 1504 and 1505) coupled with bus 1502 for processing information. Computer system 1500 also includes a main memory 1506, such as a random access memory (RAM) or other dynamic storage device, coupled to bus 1502 for storing information and instructions to be executed by processor 1504. Main memory 1506 also may be used for storing temporary variables or other intermediate information during execution of instructions to be executed by processor 1504. Computer system 1500 further includes a read only memory (ROM) 1508 or other static storage device coupled to bus 1502 for storing static information and instructions for processor 1504. A storage device 1510, such as a magnetic disk or optical disk, is provided and coupled to bus 1502 for storing information and instructions.

Computer system 1500 may be coupled via bus 1502 to a display 1512, such as a cathode ray tube (CRT) or flat panel or touch panel display for displaying information to a computer user. An input device 1514, including alphanumeric and other keys, is coupled to bus 1502 for communicating information and command selections to processor 1504. Another type of user input device is cursor control 1516, such as a mouse, a trackball, or cursor direction keys for communicating direction information and command selections to processor 1504 and for controlling cursor movement on display 1512. This input device typically has two degrees of freedom in two axes, a first axis (e.g., x) and a second axis (e.g., y), that allows the device to specify positions in a plane. A touch panel (screen) display may also be used as an input device.

One or more of the methods as described herein may be performed by computer system 1500 in response to processor 1504 executing one or more sequences of one or more instructions contained in main memory 1506. Such instructions may be read into main memory 1506 from another computer-readable medium, such as storage device 1510. Execution of the sequences of instructions contained in main memory 1506 causes processor 1504 to perform the process steps described herein. One or more processors in a multi-processing arrangement may also be employed to execute the sequences of instructions contained in main memory 1506. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 1504 for execution. Such a medium may take many forms, including but not limited to, non-volatile media, volatile media, and transmission media. Non-volatile media include, for example, optical or magnetic disks, such as storage device 1510. Volatile media include dynamic memory, such as main memory 1506. Transmission media include coaxial cables, copper wire and fiber optics, including the wires that comprise bus 1502. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 1504 for execution. For example, the instructions may initially be borne on a magnetic disk of a remote computer. The remote computer can load the instructions into its dynamic memory and send the instructions over a telephone line using a modem. A modem local to computer system 1500 can receive the data on the telephone line and use an infrared transmitter to convert the data to an infrared signal. An infrared detector coupled to bus 1502 can receive the data carried in the infrared signal and place the data on bus 1502. Bus 1502 carries the data to main memory 1506, from which processor 1504 retrieves and executes the instructions. The instructions received by main memory 1506 may optionally be stored on storage device 1510 either before or after execution by processor 1504.

Computer system 1500 also preferably includes a communication interface 1518 coupled to bus 1502. Communication interface 1518 provides a two-way data communication coupling to a network link 1520 that is connected to a local network 1522. For example, communication interface 1518 may be an integrated services digital network (ISDN) card or a modem to provide a data communication connection to a corresponding type of telephone line. As another example, communication interface 1518 may be a local area network (LAN) card to provide a data communication connection to a compatible LAN. Wireless links may also be implemented. In any such implementation, communication interface 1518 sends and receives electrical, electromagnetic or optical signals that carry digital data streams representing various types of information.

Network link 1520 typically provides data communication through one or more networks to other data devices. For example, network link 1520 may provide a connection through local network 1522 to a host computer 1524 or to data equipment operated by an Internet Service Provider (ISP) 1526. ISP 1526 in turn provides data communication services through the worldwide packet data communication network, now commonly referred to as the “Internet” 1528. Local network 1522 and Internet 1528 both use electrical, electromagnetic or optical signals that carry digital data streams. The signals through the various networks and the signals on network link 1520 and through communication interface 1518, which carry the digital data to and from computer system 1500, are exemplary forms of carrier waves transporting the information.

Computer system 1500 may send messages and receive data, including program code, through the network(s), network link 1520, and communication interface 1518. In the Internet example, a server 1530 might transmit a requested code for an application program through Internet 1528, ISP 1526, local network 1522 and communication interface 1518. One such downloaded application may provide for one or more of the techniques described herein, for example. The received code may be executed by processor 1504 as it is received, and/or stored in storage device 1510, or other non-volatile storage for later execution. In this manner, computer system 1500 may obtain application code in the form of a carrier wave.

Further embodiments have been disclosed in the following list of numbered clauses:

1. An optical arrangement for aberration correction, comprising:
a beam dispersing element for spatially dispersing a broadband radiation beam in a first transverse direction;
a focusing lens for focusing the broadband radiation beam subsequently to said dispersing, wherein said focusing lens is arranged such that the dispersed broadband radiation beam passes through at least one off-center position of the focusing lens in at least one pass, wherein said off-center position is a position displaced from a center of the focusing lens in a second transverse direction, wherein the first transverse direction and the second transverse direction are mutually perpendicular and parallel to a focal plane of the focusing lens; and
at least one aberration compensating lens displaced in the second transverse direction with respect to at least part of the broadband radiation beam so as to substantially compensate for lateral chromatic aberration imposed by the focusing lens on the at least part of the broadband radiation beam.

2. An optical arrangement as defined in clause 1, being arranged such that said broadband radiation beam passes through an off-center position of said at least one aberration compensating lens.

3. An optical arrangement as defined in clause 2, being arranged such that said off-center position of said at least one aberration compensating lens is compensatory in terms of lateral chromatic aberration to said at least one off-center position of the focusing lens.

4. An optical arrangement as defined in any preceding clause, further comprising a spectral configuration element configured to selectively transmit, diffract, or reflect the at least part of the broadband radiation beam, the at least part of the broadband radiation beam comprising one or more wavelengths of the broadband radiation beam.

5. An optical arrangement as defined in clause 4, wherein the spectral configuration element is located substantially at said focal plane of the focusing lens.

6. An optical arrangement as defined in clause 5, wherein the spectral configuration element comprises a grating light valve comprising configurable diffractive structures for selectively reflecting or diffracting the broadband radiation beam incident thereon into the at least part of the broadband radiation beam.

7. An optical arrangement as defined in clause 6, wherein the grating light valve is configured to selectively diffract the broadband radiation beam incident such that the at least part of the broadband radiation beam comprises at least one higher diffraction order selectively diffracted by the grating light valve.

8. An optical arrangement as defined in clause 7, wherein the at least one higher diffraction order comprises one or both of first (+1^{st} and −1^{st}) diffraction orders.

9. An optical arrangement as defined in clause 7 or 8, further comprising a beam block provided in a pupil plane and arranged to maximally block a zeroth diffraction order from the grating light valve while allowing maximal transmission of one or both of the first diffraction orders.

10. An optical arrangement as defined in any of clauses 6 to 9, wherein said beam dispersing element is further arranged to recombine the at least part of the broadband radiation beam into an output beam.

11. An optical arrangement as defined in clause 10, being arranged such that said broadband radiation beam passes through said center of the focusing lens to the spectral configuration element and the at least part of the broadband radiation beam passes through said at least one off-center position of the focusing lens from the spectral configuration element.

12. An optical arrangement as defined in clause 11, wherein the aberration compensating lens is displaced, with respect to said broadband radiation beam, in a direction opposite to a direction in which the focusing lens is displaced.

13. An optical arrangement as defined in clause 10, being arranged such that said broadband radiation beam passes through a first off-center position of the focusing lens to the spectral configuration element and the at least part of the broadband radiation beam passes through a second off-center position of the focusing lens from the spectral configuration element.

14. An optical arrangement as defined in clause 13, wherein the first and second off-center positions are symmetrical about the optical axis.

15. An optical arrangement as defined in any of clauses 10-14, further comprising an output lens arranged to focus the output beam; and wherein the at least one aberration compensating lens is arranged to compensate the lateral chromatic aberration imposed by the focusing lens such that wavelength dependent variation in a position of the output beam at a focal plane of the output lens is minimized.

16. An optical arrangement as defined in clause 15, wherein the at least one aberration compensating lens comprises one or both of:
said output lens, located downstream of the focusing lens; and/or
an input lens located upstream of the beam dispersing element.

17. An optical arrangement as defined in any preceding clause, wherein one or more of the focusing lens and each at least one aberration compensating lens comprise an achromatic lens.

18. An optical arrangement as defined in clause 17, wherein the achromatic lens is an achromatic doublet.

19. An optical arrangement as defined in any preceding clause, wherein the beam dispersing element comprises a prism or a grating.

20. An optical arrangement as defined in any preceding clause, wherein the broadband radiation beam comprises a spectrum partially overlapping with the range of 200 nm to 2000 nm.

21. An optical arrangement as defined in any preceding clause, wherein the broadband radiation beam comprises a spectrum partially overlapping with the range of 400 nm to 1600 nm.

22. An optical arrangement as defined in any preceding clause, wherein the broadband radiation beam comprises a spectrum having a full width half maximum (FWHM) width of at least 500 nm.

23. An optical arrangement as defined in any preceding clause, wherein the broadband radiation beam comprises a spectrum having a FWHM width of at least 300 nm.

24. An optical arrangement as defined in any preceding clause, wherein the broadband radiation beam comprises a spectrum having a FWHM width of at least 200 nm.

25. An optical arrangement as defined in any preceding clause, wherein the broadband radiation beam comprises a spectrum spanning from 500 nm to 900 nm.

26. An optical arrangement as defined in any of clauses 6 to 25, further comprising a beam shaping assembly operable to impose an elliptical profile on said broadband radiation beam to obtain an elliptical broadband radiation having a minor axis along the first transverse direction and a major axis along the second transverse direction.

27. An optical arrangement as defined in clause 26, wherein said beam shaping assembly being located upstream of the beam dispersing element.

28. An optical arrangement as defined in clause 27, wherein the beam shaping assembly is configured not to substantially change a diameter of the broadband radiation beam such that a minor-axis diameter along the minor axis of the elliptical broadband radiation beam is substantially similar to said diameter of the broadband radiation.

29. An optical arrangement as defined in any of clauses 26 to 28, wherein the beam shaping assembly comprises a pair of cylindrical lenses.

30. An optical arrangement as defined in clause 29, wherein the pair of cylindrical lenses comprises a plano-concave lens and a plano-convex lens, said plano-concave lens being located upstream of said plano-convex lens.

31. An optical arrangement as defined in any of clauses 26 to 28, wherein the beam shaping assembly comprises a pair of prisms arranged to increase a diameter of the broadband radiation beam in the second transverse direction.

32. An optical arrangement as defined in clause 31, wherein the pair of prisms comprises a first anamorphic prism and a second anamorphic prism.

33. An optical arrangement as defined in any of clauses 26 to 28, wherein the beam shaping assembly comprises a fiber bundle comprising a plurality of optical fibers; wherein at an input end of the fiber bundle, the plurality of optical fibers are arranged in a circular configuration for receiving the broadband radiation beam and at an output end of the fiber bundle, the plurality of optical fibers are arranged in a linear configuration for outputting the elliptical broadband radiation beam.

34. An optical arrangement as defined in clause 33, wherein each of the plurality of optical fibers is a multimode optical fiber having a substantially circular core.

35. An optical arrangement as defined in any of clauses 26 to 28, wherein the beam shaping assembly comprises an elliptical beam mask.

36. An optical arrangement as defined in clause 35, wherein the elliptical beam mask comprises an optical fiber having an elliptical core.

37. An optical arrangement, comprising:
a beam shaping assembly for receiving a broadband radiation beam and imposing an elliptical profile on said broadband radiation beam to obtain an elliptical broadband radiation having a minor axis along a first transverse direction and a major axis along a second transverse direction;
a beam dispersing element for spatially dispersing the elliptical broadband radiation beam in the first transverse direction;
a focusing lens for focusing the elliptical broadband radiation beam subsequently to said dispersing, wherein said focusing lens is arranged such that the dispersed elliptical broadband radiation beam passes through at least one off-center position of the focusing lens in at least one pass, wherein said off-center position is a position displaced from a center of the focusing lens in the second transverse direction, wherein the first transverse direction and the second transverse direction are mutually perpendicular and parallel to a focal plane of the focusing lens; and
a grating light valve comprising configurable diffractive structures for selectively reflecting or diffracting the focused elliptical broadband radiation beam incident thereon into at least part of the elliptical broadband radiation beam, wherein the grating light valve is arranged such that the configurable diffractive structures extend along the first transverse direction;
wherein said beam dispersing element is further arranged to recombine the at least part of the elliptical broadband radiation beam into an output beam

38. An optical arrangement as defined in clause 37, wherein the beam shaping assembly is configured not to substantially change a diameter of the broadband radiation beam such that a minor-axis diameter along the minor axis of the elliptical broadband radiation beam is substantially similar to said diameter of the broadband radiation.

39. An optical arrangement as defined in clause 37 or 38, wherein the beam shaping assembly comprises a pair of cylindrical lenses arranged to increase a diameter of the broadband radiation beam in the second transverse direction.

40. An optical arrangement as defined in clause 39, wherein the pair of cylindrical lenses comprises a plano-concave lens and a plano-convex lens, said plano-concave lens being located upstream of said plano-convex lens.

41. An optical arrangement as defined in clause 37 or 38, wherein the beam shaping assembly comprises a pair of prisms arranged to increase a diameter of the broadband radiation beam in the second transverse direction.

42. An optical arrangement as defined in clause 41, wherein the pair of prisms comprises a first anamorphic prism and a second anamorphic prism.

43. An optical arrangement as defined in clause 37 or 38, wherein the beam shaping assembly comprises a fiber bundle comprising a plurality of optical fibers; wherein at an input end of the fiber bundle, the plurality of optical fibers are arranged in a circular configuration for receiving the circular broadband radiation beam and at an output end of the fiber bundle, the plurality of optical fibers are arranged in a linear configuration for outputting the elliptical broadband radiation beam.

44. An optical arrangement as defined in clause 43, wherein each of the plurality of optical fibers is a multimode optical fiber having a substantially circular core.

45. An optical arrangement as defined in clause 37 or 38, wherein the beam shaping assembly comprises an elliptical beam mask.

46. An optical arrangement as defined in clause 45, wherein the elliptical beam mask comprises an optical fiber having an elliptical core.

47. An optical arrangement as defined in any of clauses 37 to 46, further comprising at least one aberration compensating lens displaced in the second transverse direction with respect to at least part of the broadband radiation beam so as to substantially compensate for lateral chromatic aberration imposed by the focusing lens on the at least part of the broadband radiation beam.

48. An optical arrangement as defined in clause 47, being arranged such that said broadband radiation beam passes through an off-center position of said at least one aberration compensating lens.

49. An optical arrangement as defined in clause 48, being arranged such that said off-center position of said at least one aberration compensating lens is compensatory in terms of lateral chromatic aberration to said at least one off-center position of the focusing lens.

50. An optical arrangement as defined in any of clauses 37 to 49, wherein the grating light valve is configured to selectively diffract the focused elliptical broadband radiation beam incident such that the at least part of the elliptical broadband radiation beam comprises at least one higher diffraction order selectively diffracted by the grating light valve.

51. An optical arrangement as defined in clause 50, wherein the at least one higher diffraction order comprises one or both of first (+1^{st} and −1^{st}) diffraction orders.

52. An optical arrangement as defined in clause 50 or 51, further comprising a beam block provided in a pupil plane and arranged to maximally block a zeroth diffraction order from the grating light valve while allowing maximal transmission of one or both of the first diffraction orders.

53. A metrology device comprising an optical arrangement as defined in any preceding clause.

54. A metrology device as defined in clause 47, comprising a scatterometer metrology apparatus, a level sensor or an alignment sensor.

55. A method for optimizing an optical arrangement as defined in any of clauses 1 to 52, comprising:
determining an amount of aberration imposed by the focusing lens on the broadband radiation beam; and
displacing the at least one aberration compensating lens with respect to the at least part of the broadband radiation beam to impose an amount of counter-aberration on the at least part of the broadband radiation beam so as to substantially compensate the aberration imposed by the focusing lens.

56. A method as defined in clause 55, wherein the step of determining an amount of aberration comprises:
simulating or measuring one or more positions of an output beam at a focal plane of the output lens, said output beam being formed from the at least part of the broadband radiation beam;
determining a wavelength dependent variation in the one or more positions of the output beam; and
calculating the amount of aberration based on the determined wavelength dependent variation in the one or more positions of the output radiation.

57. A method as defined in clause 55 or clause 56, wherein the at least one aberration compensating lens comprises one or both of:
an output lens located downstream of the focusing lens and
an input lens located upstream of the beam dispersing element, the method comprising:
   displacing one or both of the input lens and output lens to said amount of counter-aberration.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus.

Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1-15. (canceled)

16. An optical arrangement configured for aberration correction, comprising:
a beam dispersing element configured to spatially disperse a broadband radiation beam in a first transverse direction;
a focusing lens configured to focus the broadband radiation beam subsequently to the dispersing element, wherein:
the focusing lens is arranged such that the dispersed broadband radiation beam passes through at least one off-center position of the focusing lens in at least one pass,
the off-center position is a position displaced from a center of the focusing lens in a second transverse direction, and
the first transverse direction and the second transverse direction are mutually perpendicular and parallel to a focal plane of the focusing lens; and
at least one aberration compensating lens displaced in the second transverse direction with respect to at least part of the broadband radiation beam and configured to substantially compensate for lateral chromatic aberration imposed by the focusing lens on the at least part of the broadband radiation beam.

17. The optical arrangement of claim 16, wherein the broadband radiation beam passes through an off-center position of the at least one aberration compensating lens.

18. The optical arrangement of claim 17, wherein the off-center position of the at least one aberration compensating lens is compensatory in terms of lateral chromatic aberration to the at least one off-center position of the focusing lens.

19. The optical arrangement of claim 16, further comprising a spectral configuration element configured to selectively transmit, diffract, or reflect the at least part of the broadband radiation beam, the at least part of the broadband radiation beam comprising one or more wavelengths of the broadband radiation beam.

20. The optical arrangement of claim 19, wherein the spectral configuration element is located substantially at the focal plane of the focusing lens.

21. The optical arrangement of claim 20, wherein the spectral configuration element comprises a grating light valve comprising configurable diffractive structures configured to selectively reflect or diffract the broadband radiation beam incident thereon into the at least part of the broadband radiation beam.

22. The optical arrangement of claim 21, wherein the beam dispersing element is further arranged to recombine the at least part of the broadband radiation beam into an output beam.

23. The optical arrangement of claim 22, wherein:
the broadband radiation beam passes through the center of the focusing lens to the spectral configuration element,
the at least part of the broadband radiation beam passes through the at least one off-center position of the focusing lens from the spectral configuration element, and
the aberration compensating lens is displaced, with respect to the broadband radiation beam, in a direction opposite to a direction in which the focusing lens is displaced.

24. The optical arrangement of claim 22, wherein:
the broadband radiation beam passes through a first off-center position of the focusing lens to the spectral configuration element,
the at least part of the broadband radiation beam passes through a second off-center position of the focusing lens from the spectral configuration element, and
the first and second off-center positions are symmetrical about the optical axis.

25. The optical arrangement of claim 22, further comprising:
an output lens arranged to focus the output beam,
wherein the at least one aberration compensating lens is arranged to compensate the lateral chromatic aberration imposed by the focusing lens such that wavelength dependent variation in a position of the output beam at a focal plane of the output lens is minimized.

26. The optical arrangement as claimed in claim 25, wherein the at least one aberration compensating lens comprises one or both of:
the output lens, located downstream of the focusing lens; and/or
an input lens located upstream of the beam dispersing element.

27. The optical arrangement of claim 16, wherein the broadband radiation beam comprises a spectrum partially overlapping with the range of 200 nm to 2000 nm.

28. The optical arrangement of claim 16, wherein the broadband radiation beam comprises a spectrum having a FWHM width of at least 200 nm.

29. A metrology device comprising the optical arrangement of claim 16.

30. A method for optimizing an optical arrangement of claim 16, comprising:
determining an amount of aberration imposed by the focusing lens on the broadband radiation beam; and
displacing the at least one aberration compensating lens with respect to the at least part of the broadband radiation beam to impose an amount of counter-aberration on the at least part of the broadband radiation beam so as to substantially compensate the aberration imposed by the focusing lens.
